(19) United States
(12) Patent Application Publication
(10) Pub. No.: US 2026/0164831 A1
(43) Pub. Date: Jun. 11, 2026

(54) Sensing Substrate, Sensing Device

(71) Applicants: Beijing BOE Optoelectronics Technology Co., Ltd., Beijing (CN); BOE Technology Group Co., Ltd., Beijing (CN)

(72) Inventors: Dexi KONG, Beijing (CN); Jie ZHANG, Beijing (CN); Cheng LI, Beijing (CN); Lin ZHOU, Beijing (CN); Gen HUANG, Beijing (CN); Zixiao CHEN, Beijing (CN); Yingzi WANG, Beijing (CN); Shan ZHANG, Beijing (CN)

(21) Appl. No.: 18/705,580

(22) PCT Filed: Aug. 18, 2023
(86) PCT No.: PCT/CN2023/113784

§ 371 Date: Apr. 28, 2024

(51) Int. Cl. H10F 39/00

(52) U.S. Cl. CPC H10F 39/811; H10F 39/80373

(57) ABSTRACT

A sensing substrate and a sensing device, the sensing substrate includes a sensing region the sensing region includes multiple signal wires, on a plane parallel to the sensing substrate, an anti-static element and a fan-out region are provided on at least one side of the sensing region the anti-static element is on a side of the fan-out region away from the sensing region, and at least part of the signal wires in the sensing region are electrically connected with the anti-static element through fan-out wires in the fan-out region.

### CROSS-REFERENCE TO RELATED APPLICATION

The present application is a U.S. National Phase Entry of International Application PCT/CN 2023/113784 having an international filing date of Aug. 18, 2023, and entitled “Sensing Substrate, Sensing Device”, the contents of which are hereby incorporated by reference in their entireties.

### TECHNICAL FIELD

Embodiments of the present disclosure relate to, but are not limited to, the field of semiconductor technologies, and more particularly to a sensing substrate and a sensing device.

### BACKGROUND

With the development of society and intelligent construction in cities, transportation, industry and other fields, image sensors have been applied to all aspects of life, such as industry, national defense, vehicle mounted equipment, consumer electronics, medical, so image sensors have broad market prospects.

### SUMMARY

The following is a summary of subject matter described herein in detail. The summary is not intended to limit the scope of protection of the claims.

In a first aspect, an embodiment of the present disclosure provides a sensing substrate, including a sensing region, wherein the sensing region includes multiple signal wires, on a plane parallel to the sensing substrate, an anti-static element and a fan-out region are provided on at least one side of the sensing region, the anti-static element is on a side of the fan-out region away from the sensing region, and at least part of the signal wires in the sensing region are electrically connected with the anti-static element through fan-out wires in the fan-out region.

In an exemplary implementation, the sensing substrate further includes a drive port, the anti-static element includes a first anti-static unit, and the fan-out region includes a first anti-static fan-out region;

on a plane parallel to the sensing substrate, the sensing region includes a first side and a second side disposed opposite to each other along a first direction, on the first direction, the drive port is on a side of the first side away from the second side, the first anti-static unit is on a side of the second side away from the first side, and the first anti-static fan-out region is between the sensing region and the first anti-static unit.

In an exemplary implementation, a size of a side of the first anti-static fan-out region close to the sensing region along a second direction is less than a size of a side of the first anti-static fan-out region close to the first anti-static unit along the second direction, on a plane parallel to the sensing substrate, the first direction intersects with the second direction.

In an exemplary implementation, a bias element is further provided on at least one side of the sensing region, the first anti-static fan-out region includes a third drive fan-out region and a fourth drive fan-out region, and the bias element includes a first bias unit.

On the side of the second side away from the first side and along a direction from the first side to the second side, the third drive fan-out region, the first bias unit, the fourth drive fan-out region, and the first anti-static unit are sequentially arranged. One end of at least one fan-out wire in the third drive fan-out region is connected with at least part of the signal wires in the sensing region, and the other end of the at least one fan-out wire in the third drive fan-out region is electrically connected with the first anti-static unit through a fan-out wire in the fourth drive fan-out region.

In an exemplary implementation, a size of a side of the third drive fan-out region close to the sensing region along the second direction is less than a size of a side of the third drive fan-out region close to the fourth drive fan-out region along the second direction; a size of a side of the fourth drive fan-out region close to the third drive fan-out region along the second direction is less than a size of a side of the fourth drive fan-out region close to the first anti-static unit along the second direction.

In an exemplary implementation, the multiple signal wires in the sensing region include multiple scan signal lines extending along the first direction and arranged at intervals along the second direction; the first anti-static unit includes multiple first static discharge circuits arranged at intervals along the second direction; the first bias unit includes a first bias structure layer; in a direction perpendicular to a plane where the sensing substrate is located, the sensing substrate includes a base substrate, a first conductive layer disposed on the base substrate, a second conductive layer disposed on a side of the first conductive layer away from the base substrate, and a first electrode layer disposed on a side of the second conductive layer away from the base substrate.

The first conductive layer includes multiple scan signal lines located in the sensing region and multiple third scan fan-out lines located in the third drive fan-out region and the multiple third scan fan-out lines are configured to be connected with the multiple scan signal lines of the sensing region.

The second conductive layer includes multiple fourth scan fan-out lines located in the fourth drive fan-out region and the multiple fourth scan fan-out lines are configured to respectively connect the multiple third scan fan-out lines with the multiple first static discharge circuits in a jumper manner.

The first electrode layer includes a first bias structure layer.

In an exemplary implementation, the first bias unit further includes a first bias auxiliary structure layer located at the first conductive layer, the first bias auxiliary structure layer is electrically connected with the first bias structure layer; an orthographic projection of the first bias structure layer on the base substrate is overlapped with an orthographic projection of the first bias auxiliary structure layer on the base substrate.

In an exemplary implementation, the first bias unit further includes multiple first bias bridge structures located at the second conductive layer, the multiple first bias bridge structures extend along the first direction, are arranged at intervals along the second direction, and are electrically connected with the first bias structure layer and the first bias auxiliary structure layer.

The first bias structure layer and the first bias auxiliary structure layer are provided with multiple first hollow regions, so that the first bias unit forms a grid-like structure, an orthographic projection of the multiple fourth scan fan-out lines on the base substrate is not overlapped with an orthographic projection of the multiple first bias bridge structures on the base substrate, and the multiple fourth scan fan-out lines respectively extend to the third drive fan-out region along the first direction through the intervals between the multiple first bias bridge structures.

In an exemplary implementation, the fan-out region further includes a first drive fan-out region and a second drive fan-out region, the anti-static element further includes a second anti-static unit, the second drive fan-out region is on a side of the first side away from the second side, the second anti-static unit is on a side of the second drive fan-out region away from the sensing region, the first drive fan-out region is on a side of the second anti-static unit away from the second drive fan-out region, the drive port is on a side of the first drive fan-out region away from the sensing region, the second anti-static unit is located on a side of the first drive fan-out region away from the sensing region, the second anti-static unit is electrically connected with a fan-out wire in the first drive fan-out region and a fan-out wire in the second drive fan-out region, one end of at least one fan-out wire in the first drive fan-out region is electrically connected with multiple scan signal lines in the sensing region through a fan-out wire in the second drive fan-out region, and the other end of the at least one fan-out wire in the first drive fan-out region is electrically connected with the drive port.

In an exemplary implementation, a size of a side of the second drive fan-out region close to the first drive fan-out region along the second direction is greater than a size of a side of the second drive fan-out region close to the sensing region along the second direction; a size of a side of the first drive fan-out region away from the second drive fan-out region along the second direction is less than a size of a side of the first drive fan-out region close to the second drive fan-out region along the second direction.

In an exemplary implementation, the sensing substrate further includes a first power supply connection line and a second power supply connection line located at the second conductive layer and a third power supply connection line located at the first conductive layer; the second anti-static unit includes multiple second static discharge circuits arranged at intervals along the second direction; on a plane parallel to the sensing substrate, the first power supply connection line and the second power supply connection line extend along the second direction, the third power supply connection line extends along the first direction, and the sensing region further includes a third side and a fourth side disposed opposite to each other along the second direction.

The first power supply connection line is on a side of the second anti-static unit away from the sensing region and is electrically connected with multiple second static discharge circuits in the second anti-static unit.

The second power supply connection line is on the side of the second anti-static unit away from the sensing region and is electrically connected with multiple first static discharge circuits in the second anti-static unit.

The third power supply connection line is on a side of the third side away from the fourth side and two ends of the third power supply connection line are electrically connected with the first power supply connection line and the second power supply connection line respectively.

In an exemplary implementation, the sensing substrate further includes a fourth power supply connection line and a fifth power supply connection line located at the first conductive layer, on the second direction, the fourth power supply connection line and the fifth power supply connection line are at two sides of the first drive fan-out region and the first power supply connection line respectively, on the first direction, one end of the fourth power supply connection line is electrically connected with the first power supply connection line and the other end of the fourth power supply connection line is connected with the drive port, and one end of the fifth power supply connection line is electrically connected with the third power supply connection line and the other end of the fifth power supply connection line is connected with the drive port.

In an exemplary implementation, the first conductive layer further includes multiple first scan fan-out lines located at the first drive fan-out region and multiple second scan fan-out lines located at the second drive fan-out region, the multiple second scan fan-out lines are configured to be connected with the multiple scan signal lines, and the multiple first scan fan-out lines are configured to connect the multiple second scan fan-out lines with the drive port.

In an exemplary implementation, the sensing substrate further includes a read port, the sensing region further includes a third side and a fourth side disposed opposite to each other along the second direction, the fan-out region further includes a first data fan-out region and a second data fan-out region, and the bias element further includes a second bias unit; on the second direction, the second data fan-out region is on a side of the fourth side away from the third side, the first data fan-out region is on a side of the second data fan-out region away from the sensing region, the second bias unit is between the first data fan-out region and the second data fan-out region, the read port is on a side of the first data fan-out region away from the sensing region, one end of at least one fan-out wire in the first data fan-out region is electrically connected with at least part of the signal wires in the sensing region through a fan-out wire in the second data fan-out region, and the other end of the at least one fan-out wire in the first data fan-out region is electrically connected with the read port.

In an exemplary implementation, the multiple signal wires in the sensing region include multiple data signal lines located at the second conductive layer, the multiple data signal lines extend along the second direction and are arranged at intervals along the first direction; the second bias unit includes a second bias structure layer.

The second conductive layer further includes multiple first data fan-out lines located in the first data fan-out region and multiple second data fan-out lines located in the second data fan-out region, the multiple second data fan-out lines are configured to be connected with the multiple data signal lines, and the multiple first data fan-out lines are configured to connect the multiple second data fan-out lines with the read port.

The first electrode layer further includes the second bias structure layer and the second bias structure layer is electrically connected with the first bias structure layer.

In an exemplary implementation, the second bias unit further includes a second bias auxiliary structure layer located at the first conductive layer and multiple second bias bridge structures located at the second conductive layer.

The second bias auxiliary structure layer is electrically connected with the second bias structure layer and an orthographic projection of the second bias structure layer on the base substrate is overlapped with an orthographic projection of the second bias auxiliary structure layer on the base substrate.

The multiple second bias bridge structures extend along the second direction, are arranged at intervals along the first direction, and are electrically connected with the second bias structure layer and the second bias auxiliary structure layer.

The second bias structure layer and the second bias auxiliary structure layer are provided with multiple second hollow regions, so that the second bias unit forms a grid-like structure, an orthographic projection of the multiple first data fan-out lines on the base substrate is not overlapped with an orthographic projection of the multiple second bias bridge structures on the base substrate, and the multiple first data fan-out lines respectively extend to the second drive fan-out region along the second direction through the intervals between the multiple second bias bridge structures.

In an exemplary implementation, the sensing substrate further includes a read port, a first bias wire and a second bias wire located at the second conductive layer, on the first direction, the first bias wire and the second bias wire are on two sides of the second bias unit and the first data fan-out region, on the second direction, the first bias wire and the second bias wire are on a side of the second bias unit away from the sensing region, each of the first bias wire and the second bias has one end connected with the second bias unit and the other end connected with the read port.

In an exemplary implementation, the bias element further includes a third bias unit located on the side of the third side away from the fourth side, on the second direction, the third bias unit is between the sensing region and the third power supply connection line, and the third bias unit includes a third bias structure layer located at the first electrode layer, a third bias auxiliary structure layer located at the first conductive layer, and multiple third bias bridge structures located at the second conductive layer.

The third bias auxiliary structure layer is electrically connected with the third bias structure layer and the third bias structure layer is electrically connected with the first bias structure layer; an orthographic projection of the third bias structure layer on the base substrate is overlapped with an orthographic projection of the third bias auxiliary structure layer on the base substrate.

The multiple third bias bridge structures extend along the second direction, are arranged at intervals along the first direction, and are electrically connected with the third bias structure layer and the third bias auxiliary structure layer.

The third bias structure layer and the third bias auxiliary structure layer are provided with multiple third hollow regions, so that the third bias unit forms a grid-like structure.

In an exemplary implementation, the multiple signal wires in the sensing region include multiple data signal lines located at the second conductive layer, the multiple data signal lines extend along the second direction and are arranged at intervals along the first direction; the multiple data signal lines and the multiple scan signal lines define multiple pixel areas; at least part of the pixel area is provided with a thin film transistor and a first electrode, the first electrode is at the first electrode layer, and an orthographic projection of the first electrode on the base substrate is overlapped with an orthographic projection of a corresponding thin film transistor on the base substrate.

In an exemplary implementation, the thin film transistor includes a gate electrode located at the first conductive layer, a source electrode and a drain electrode located at the second conductive layer, and an active layer located between the first conductive layer and the second conductive layer, wherein the source electrode is electrically connected with a corresponding first electrode and the drain electrode and a corresponding data signal line are of an integrally formed structure.

In an exemplary implementation, on a plane parallel to the sensing substrate, a size of a pixel area along the first direction is 10 microns to 20 microns and a size of the pixel area along the second direction is 10 microns to 20 microns.

In an exemplary implementation, on a plane parallel to the sensing substrate, in a same pixel area, on the first direction, a size of a data signal line is 1 micron to 2 microns, a distance between the data signal line and an opposite side surface of a corresponding first electrode is 0.9 micron to 1.9 microns, and a distance between the drain electrode and an opposite side surface of a corresponding source electrode is 1.5 microns to 2.5 microns; on the second direction, a size of the scan signal line is 1 micron to 2 microns, a distance between the scan signal line and an opposite side surface of a corresponding first electrode is 0.8 micron to 1.8 microns, and a size of the active layer is 2.5 microns to 3.5 microns.

In an exemplary implementation, the sensing substrate further includes an insulation layer located between the second conductive layer and the first electrode layer on the direction perpendicular to the plane where the sensing substrate is located, the insulation layer is provided with multiple first vias; the second conductive layer is further provided with multiple first switch electrodes, the multiple first switch electrodes are integrally formed with source electrodes of corresponding thin film transistors, and the multiple first electrodes are electrically connected with corresponding first switch electrodes through the multiple first vias; an orthographic projection of the multiple first vias on the base substrate is respectively overlapped with an orthographic projection of the multiple first electrodes on the base substrate and an orthographic projection of the multiple first switch electrodes on the base substrate.

In an exemplary implementation, the first conductive layer further includes gate electrodes of the thin film transistor, the gate electrodes are integrally formed with corresponding scan signal line, a shape of each first switch electrode is a polygonal, and on the second direction, the first switch electrode is on a side of a corresponding source electrode; a size of a side of the first switch electrode close to a corresponding source electrode along the first direction is less than a size of a side of the first switch electrode away from the corresponding source electrode along the first direction; an orthographic projection of a side of the first switch electrode connected with the corresponding source electrode on the base substrate is at least partially overlapped with an orthographic projection of a corresponding gate electrode on the base substrate, and one end of the first switch electrode away from the corresponding source electrode is electrically connected with a corresponding first electrode through a first via.

In an exemplary implementation, on the direction perpendicular to the plane where the sensing substrate is located, at least part of the first electrodes include a first functional layer and a second functional layer, the second functional layer is on a side of the first functional layer away from the base substrate, and an orthographic projection of the first functional layer on the base substrate is overlapped with and an orthographic projection of a corresponding second functional layer on the base substrate.

In an exemplary implementation, the first functional layer is provided with multiple open apertures, in a plane parallel to the sensing substrate, an aperture size of an open aperture is 1.5 microns to 5 microns.

In an exemplary implementation, on the direction perpendicular to the plane where the sensing substrate is located, the insulation layer includes a second insulation layer, a planarization layer, and a third insulation layer that are sequentially disposed on the side of the second conductive layer away from the base substrate, or the insulation layer includes a second insulation layer and a third insulation layer that are disposed on a side of the second conductive layer away from the base substrate.

In an exemplary implementation, on a plane parallel to the sensing substrate, an aperture size of the first via is 1.5 microns to 2.5 microns.

In an exemplary implementation, on a plane parallel to the sensing substrate, a distance between the bias element and the sensing region is greater than or equal to 8.6 mm.

In a second aspect, an embodiment of the present disclosure further provides a sensing device, including a detection layer and the sensing substrate of any of the above embodiments, wherein the sensing substrate includes a base substrate and a read layer disposed on the base substrate, and the detection layer is disposed on a side of the read layer away from the base substrate.

In an exemplary implementation, on a plane parallel to the sensing substrate, the sensing substrate includes a sensing region and the sensing region is provided with multiple first electrodes electrically connected with the read layer; in a direction perpendicular to a plane where the sensing substrate is located, the multiple first electrodes are on a side of the read layer away from the base substrate, and the detection layer includes a photoelectric conversion layer disposed on a side of the first electrodes away from the base substrate, and a second electrode layer disposed on a side of the photoelectric conversion layer away from the base substrate.

In an exemplary implementation, on a plane parallel to the sensing substrate, a bias element is provided on at least one side of the sensing region and the bias element is electrically connected with the second electrode layer and configured to provide a bias voltage to the second electrode layer.

Other aspects of the present disclosure may be comprehended after the drawings and the detailed descriptions are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of each component in the drawings do not reflect actual scales, but are only intended to schematically illustrate contents of the present disclosure.

FIG. 1a shows a schematic diagram of a planar structure of a sensing substrate according to an exemplary embodiment of the present disclosure.

FIG. 1b shows a schematic partial enlarged view of M1 position in FIG. 1a.

FIG. 1c shows a schematic partial enlarged view of M2 position in FIG. 1a.

FIG. 1d shows a schematic diagram of a planar structure of a first conductive layer in FIG. 1b.

FIG. 1e shows a schematic diagram of a planar structure of a second conductive layer in FIG. 1b.

FIG. 1f shows a schematic partial enlarged view of M3 position in FIG. 1a.

FIG. 1g shows a schematic partial enlarged view of M4 position in FIG. 1a.

FIG. 1h shows a schematic partial enlarged view of M5 position in FIG. 1a.

FIG. 1i shows a schematic partial enlarged view of M6 position in FIG. 1a.

FIG. 1j shows a schematic diagram of a planar structure of a third bias auxiliary structure layer in FIG. 1i.

FIG. 1k shows a schematic diagram of a planar structure of a plurality of third bias bridge structures in FIG. 1i.

FIG. 1l shows another schematic partial enlarged view of M6 position in FIG. 1a.

FIG. 2a shows a schematic view of a cross-sectional structure along position C-C in FIG. 1i.

FIG. 2b shows another schematic view of a cross-sectional structure along position C-C in FIG. 1i.

FIG. 2c shows a schematic view of a cross-sectional structure along position D-D in FIG. 11.

FIG. 2d shows another schematic view of a cross-sectional structure along position C-C in FIG. 1i.

FIG. 2e shows another schematic view of a cross-sectional structure along position C-C in FIG. 1i.

FIG. 2f shows a schematic view of a cross-sectional structure of a sensing device according to an exemplary embodiment of the present disclosure.

FIG. 3 shows a schematic diagram of a planar structure after a pattern of a first conductive layer is formed according to an exemplary embodiment of the present disclosure.

FIG. 4 shows a cross-sectional view taken along A-A direction in FIG. 3.

FIG. 5 shows a schematic diagram of a planar structure after a pattern of a semiconductor layer is formed according to an exemplary embodiment of the present disclosure.

FIG. 6 shows a cross-sectional view taken along A-A direction in FIG. 5.

FIG. 7 shows a schematic diagram of a planar structure after a pattern of a second conductive layer is formed according to an exemplary embodiment of the present disclosure.

FIG. 8 shows a cross-sectional view taken along A-A direction in FIG. 7.

FIG. 9 shows a schematic diagram of a planar structure after a pattern of a third insulation layer is formed according to an exemplary embodiment of the present disclosure.

FIG. 10a shows a cross-sectional view taken along A-A direction in FIG. 9.

FIG. 10b shows a cross-sectional view taken along B-B direction in FIG. 9.

FIG. 10c shows another cross-sectional view taken along A-A direction in FIG. 9.

FIG. 10d shows another cross-sectional view taken along B-B direction in FIG. 9.

FIG. 11 shows a schematic diagram of a planar structure after a pattern of a first electrode layer is formed according to an exemplary embodiment of the present disclosure.

FIG. 12a shows a cross-sectional view taken along A-A direction in FIG. 11.

FIG. 12b shows a cross-sectional view taken along B-B direction in FIG. 11.

FIG. 12c shows another cross-sectional view taken along B-B direction in FIG. 11.

FIG. 12d shows another cross-sectional view taken along B-B direction in FIG. 11.

FIG. 13a shows a schematic diagram of a planar structure of a first functional layer in FIG. 12c.

FIG. 13b shows a schematic diagram of a planar structure of a first functional layer in FIG. 12d FIG. 14a shows a schematic diagram of a planar structure after a pattern of a photoelectric conversion layer is formed according to an exemplary embodiment of the present disclosure.

FIG. 14b shows another schematic diagram of a planar structure after a pattern of a photoelectric conversion layer is formed according to an exemplary embodiment of the present disclosure.

FIG. 15 shows a cross-sectional view taken along B-B direction in FIG. 14a and FIG. 14b.

FIG. 16 shows a schematic diagram of a planar structure after a pattern of a second electrode layer is formed according to an exemplary embodiment of the present disclosure.

FIG. 17 shows a cross-sectional view taken along B-B direction in FIG. 16.

FIG. 18 shows a schematic diagram of a planar structure after a pattern of a protective layer is formed according to an exemplary embodiment of the present disclosure.

FIG. 19 shows a cross-sectional view taken along B-B direction in FIG. 18.

### DETAILED DESCRIPTION

Embodiments of the present disclosure will be described in detail hereinafter with reference to the drawings. Implementations may be implemented in multiple different forms. Those of ordinary skills in the art can easily understand such a fact that implementations and contents may be transformed into various forms without departing from the purpose and scope of the present disclosure. Therefore, the present disclosure should not be construed as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Ordinal numerals “first”, “second”, “third”, etc., in the specification are set not to form limits in numbers but only to avoid confusion between composition elements.

In the specification, unless otherwise specified and defined, terms “mounting”, “mutual connection”, and “connection” should be understood in a broad sensing. For example, a connection may be fixed connection, or detachable connection, or integral connection; it may be mechanical connection or electrical connection; it may be direct connection, or indirect connection through an intermediate, or internal communication between two elements. Those of ordinary skills in the art can understand specific meanings of the above terms in the present disclosure according to specific situations.

In the specification, “electrical connection” includes connection of composition elements through an element with a certain electrical action. An “element with a certain electrical action” is not particularly limited as long as electric signals between the connected composition elements may be sent and received. Examples of the “element with a certain electric action” not only include an electrode and a wiring, but also may include a switch element such as a transistor or the like, a resistor, an inductor, a capacitor, another element with one or more functions, or the like.

In the embodiments of the present disclosure, a transistor refers to an element that at least includes three terminals, i.e., a gate electrode, a drain electrode, and a source electrode. A transistor has a channel region between a drain electrode (or referred to as a drain electrode terminal, a drain connection region, or a drain) and a source electrode (or referred to as a source electrode terminal, a source connection region, or a source), and a current can flow through the drain electrode, the channel region, and the source electrode. In the embodiments of the present disclosure, a channel region refers to a region through which a current mainly flows.

In the embodiments of the present disclosure, a first electrode may be a drain electrode while a second electrode may be a source electrode, or a first electrode may be a source electrode while a second electrode may be a drain electrode, and a third electrode may be a control electrode. Functions of the “source electrode” and the “drain electrode” are sometimes interchangeable in a situation in which transistors with opposite polarities are used or a current direction changes during working of a circuit. Therefore, in the embodiments of the present disclosure, the “source electrode” and the “drain electrode” are interchangeable. The “source electrode” and the “drain electrode” may be referred to as a “source” and a “drain”, and the gate electrode may be referred to as a control electrode or a third electrode.

An image sensor usually includes a base substrate, a backplane (the backplane may be referred to as a read circuit or a read layer) and a detection layer that are sequentially disposed on the base substrate. According to a type of the backplane, image sensors may include glass-base image sensors and silicon-base image sensors. A detection layer and a read circuit of a silicon-base image sensor are bonded. According to differences in detection bands and sensitive materials, various bonding processes (anodic bonding, high and low temperature direct bonding, hot pressing bonding and eutectic bonding, etc.) are derived. However, a bonding process is complex and has a low yield. Taking a short-wave infrared image sensor as an example, a traditional InGaAs (indium gallium arsenic) short-wave infrared image sensor interconnect an indium gallium arsenic epitaxial wafer and a silicon-base read circuit through an indium column or a copper column flip-chip bond using a flip-chip bonding manner, which leads to a high cost and a low yield of a semiconductor epitaxial growth, resulting in a greatly increased cost. Development and maturity of a new technology requires a lot of technical verification. However, an interconnection verification between a silicon-base read circuit and a new detection sensitive material is not cost-effective for verifying a new photoelectric sensitive material because of a complex process and a high cost of the silicon-base read circuit. However, when a glass-base read circuit is used to verify a new sensitive material, because pixels are too large, a pixel density (full name Pixels Per Inch, PPI for short) of the glass-base read circuit is difficult to meet pixel specification requirements of a silicon-base read circuit.

An embodiment of the present disclosure provides a sensing substrate, which may include a sensing region, the sensing region includes multiple signal wires. On a plane parallel to the sensing substrate, a fan-out region and an anti-static element are provided on at least one side of the sensing region. The anti-static element is on a side of the fan-out region away from the sensing region, and at least part of signal wires in the sensing region are electrically connected with the anti-static element through a fan-out wire in the fan-out region.

In the sensing substrate provided by the embodiment of the present disclosure, the anti-static element is provided on the side of the fan-out region away from the sensing region, and at least part of the signal wires in the sensing region are electrically connected with the anti-static element through the fan-out wire in the fan-out region, so that the sensing substrate may be applied to a pixel specification with a high PPI.

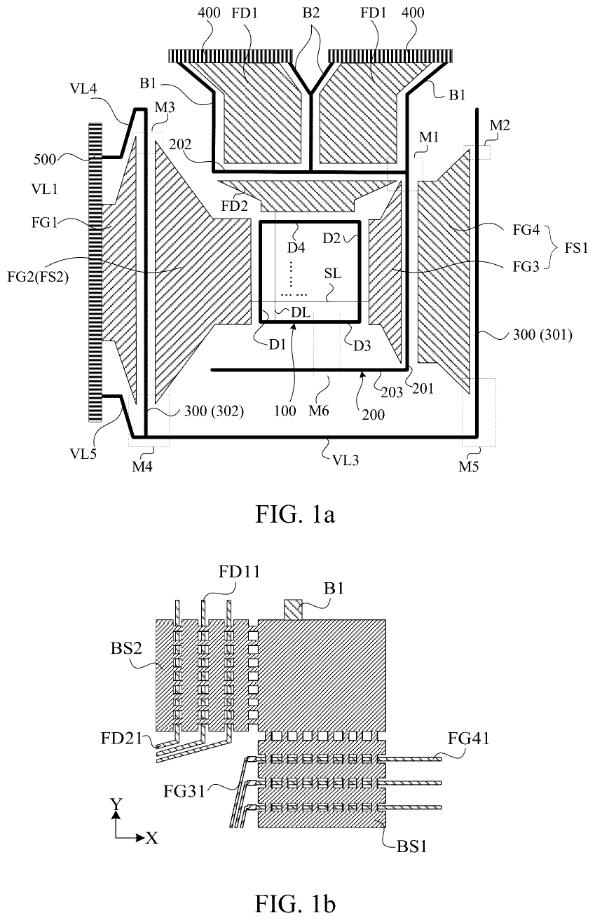

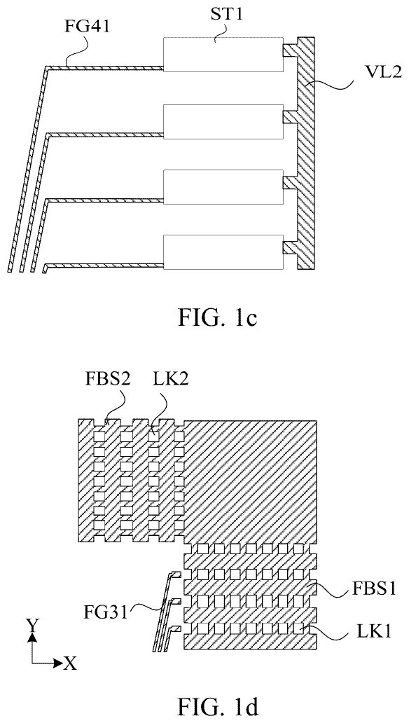

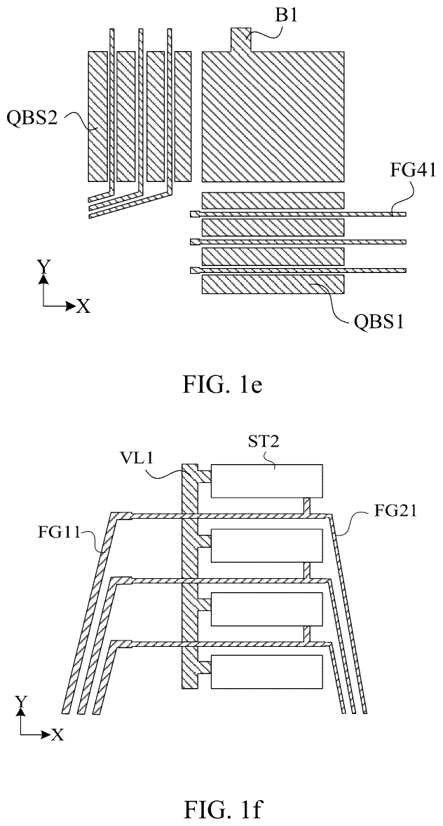

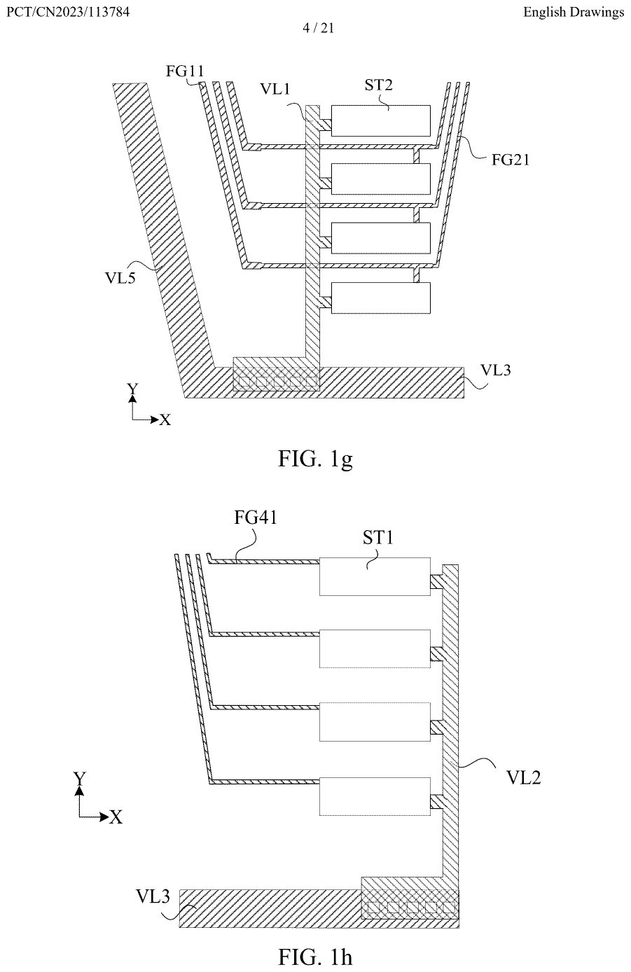

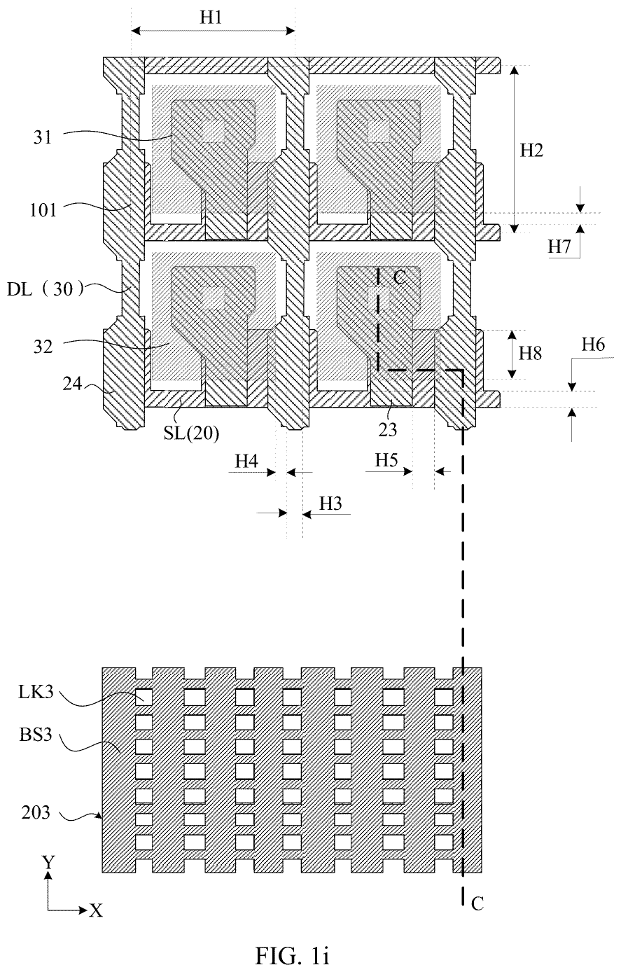

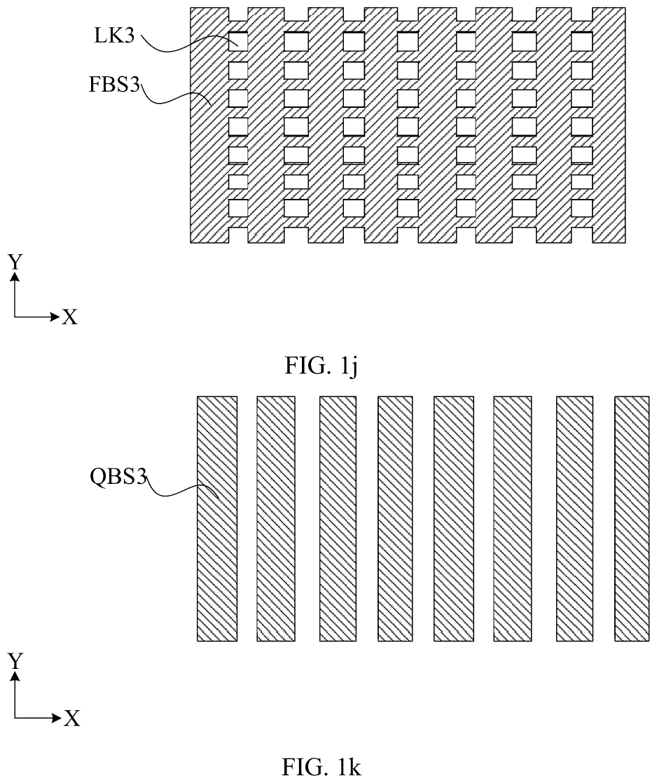

FIG. 1a is a schematic diagram of a planar structure of a sensing substrate according to an exemplary embodiment of the present disclosure. As shown in FIG. 1, the sensing substrate may include a sensing region 100, the sensing region 100 may include multiple signal wires, and on a plane parallel to the sensing substrate, a fan-out region and an anti-static element 300 are provided on at least one side of the sensing region 100., The anti-static element 300 is on a side of the fan-out region away from the sensing region 100, and at least part of the signal wires in the sensing region 100 are electrically connected with the anti-static element 300 through a fan-out wire in a fan-out region.

In an exemplary implementation, as shown in FIG. 1a, the sensing substrate may further include a drive port 500, the anti-static element 300 may include a first anti-static unit 301, and the fan-out region may include a first anti-static fan-out region FS1.

In a plane parallel to the sensing substrate, the sensing region 100 may include a first side D1 and a second side D2 disposed opposite to each other along a first direction X. In the first direction, the drive port 500 is on a side of the first side D1 away from the second side D2, the first anti-static unit 301 is on a side of the second side D2 away from the first side D1, and the first anti-static fan-out region FS1 is between the sensing region 100 and the first anti-static unit 301.

In an exemplary implementation, a size of a side of the first anti-static fan-out region FS1 close to the sensing region 100 along a second direction Y is less than a size of a side of the first anti-static fan-out region FS1 close to the first anti-static unit 301 along the second direction Y, and the first direction X intersects with the second direction Y in a plane parallel to the sensing substrate.

In an exemplary implementation, as shown in FIG. 1a, the multiple signal wires in the sensing region 100 generally includes multiple scan signal lines SL extending along the first direction X and arranged at intervals along the second direction Y. The sensing region 100 may be provided with multiple identification pixels arranged in an array. In one case, an area of the sensing region 100 is correspondingly decreased as a total quantity of pixels in the sensing region 100 is unchanged and a single pixel becomes smaller to increase the PPI. Since a total quantity of pixel rows is not changed, if the anti-static element 300 becomes smaller as the sensing region 100 becomes smaller, an anti-static capability of the anti-static element 300 will decrease, it is necessary to connect the multiple scan signal lines SL in the sensing region with the first anti-static unit 301 through fan-out wires in the fan-out region to adapt to a high PPI sensing substrate. In another case, an area of the sensing region 100 is unchanged and the pixels become smaller and the PPI is increased, so a total quantity of pixels will be increased correspondingly. As the total quantity of pixels is increased, a quantity of pixel rows is increased and a quantity of the scan signal lines SL in the sensing region 100 is increased. Therefore, it is necessary to increase a size of the first anti-static unit 301 along the second direction Y. Therefore, it is necessary to provide a first anti-static fan-out region FS1 to connect the multiple scan signal lines SL in the sensing region 100 with the first anti-static unit 301 to adapt to a high PPI sensing substrate.

In an exemplary implementation, as shown in FIG. 1a, a bias element 200 is further provided on at least one side of the sensing region 100, the first anti-static fan-out region FS1 may include a third drive fan-out region FG3 and a fourth drive fan-out region FG4, and the bias element 200 may include a first bias unit 201.

The third drive fan-out region FG3, the first bias unit 201, the fourth drive fan-out region FG4, and the first anti-static unit 301 are sequentially arranged along a direction from the first side D1 to the second side D2 on the side of the second side D2 away from the first side D1. One end(s) of fan-out wire(s) in the third drive fan-out region FG3 is connected with at least part of the signal wires in the sensing region 100, and the other end(s) of the fan-out wire(s) in the third drive fan-out region FG3 is electrically connected with the first anti-static unit 301 through fan-out wires in the fourth drive fan-out region FG4.

In an exemplary implementation, as shown in FIG. 1a, a size of a side of the third drive fan-out region FG3 close to the sensing region 100 along the second direction Y is less than a size of a side of the third drive fan-out region FG3 close to the fourth drive fan-out region FG4 along the second direction Y. A size of a side of the fourth drive fan-out region FG4 close to the third drive fan-out region FG3 along the second direction Y is less than a size of a side of the fourth drive fan-out region FG4 close to the first anti-static unit 301 along the second direction Y.

In an exemplary implementation, in the case where the area of the sensing region 100 is correspondingly decreased as the total quantity of pixels in the sensing region 100 is unchanged and a single pixel becomes smaller to increase the PPI, the bias element 200 may correspondingly become smaller as the area of the sensing region 100 is decreased. Since the total quantity of pixel rows is not changed, the anti-static element 300 becomes smaller as the sensing region 100 becomes smaller, the anti-static capability of the anti-static element 300 will decrease, it is necessary to connect the multiple scan signal lines SL in the sensing region 100 with the first anti-static unit 301 through the fan-out wires in the third drive fan-out region FG3 and in the fourth drive fan-out region FG4 to adapt to a high PPI sensing substrate. In another case where the area of the sensing region 100 is unchanged and the pixels become smaller and the PPI is increased, so the total quantity of pixels will be increased correspondingly, the bias element 200 may be consistent with the sensing region 100 in area. As the total quantity of pixels is increased, the quantity of pixel rows is increased and the quantity of scan signal lines SL in the sensing region 100 is increased. Therefore, it is necessary to increase the size of the first anti-static unit 301 along the second direction Y. Therefore, it is necessary to provide fan-out wires in the third drive fan-out region FG3 and in the fourth drive fan-out region FG4 to connect the multiple scan signal lines SL in the sensing region 100 with the first anti-static unit 301 to adapt to a high PPI sensing substrate.

In an exemplary implementation, as shown in FIG. 1a to FIG. 1c, FIG. 1b is a schematic partial enlarged view of M1 position in FIG. 1a, and FIG. 1c is a schematic partial enlarged view of M2 position in FIG. 1a. The multiple signal wires in the sensing region 100 may include multiple scan signal lines SL extending along the first direction X and arranged at intervals along the second direction Y. The first anti-static unit 301 may include multiple first static discharge circuits ST1 arranged at intervals along the second direction Y. The first bias unit 201 may include a first bias structure layer BS1, In a direction perpendicular to a plane where the sensing substrate is located, the sensing substrate may include a base substrate 10, a first conductive layer disposed on the base substrate, a second conductive layer disposed on a side of the first conductive layer away from the base substrate 10, and a first electrode layer disposed on a side of the second conductive layer away from the base substrate.

The first conductive layer may include multiple scan signal lines SL located in the sensing region 100 and multiple third scan fan-out lines FG31 located in the third drive fan-out region FG3. The multiple third scan fan-out lines FG31 are configured to be connected with the multiple scan signal lines SL in the sensing region 100.

The second conductive layer may include multiple fourth scan fan-out lines FG41 located in the fourth drive fan-out region FG4. The multiple fourth scan fan-out lines FG41 are configured to connect the multiple third scan fan-out lines FG31 with the multiple first static discharge circuits ST1 respectively in a jumper manner.

The first electrode layer may include the first bias structure layer BS1.

In an exemplary implementation, the multiple first static discharge circuits ST1 may be configured to discharge static electricity in the multiple scan signal lines SL through the multiple fourth scan fan-out lines FG41 and the multiple third scan fan-out lines FG31. In an exemplary implementation, the multiple first static discharge circuits ST1 are electrically connected with the multiple fourth scan fan-out lines FG41 and the multiple third scan fan-out lines FG31, and thus may be configured to discharge static electricity in the multiple fourth scan fan-out lines FG41 or the multiple third scan fan-out lines FG31.

In an exemplary implementation, as shown in FIG. 1d, FIG. 1d is a schematic diagram of a planar structure of a first conductive layer in FIG. 1b (the M1 position in FIG. 1a), the first bias unit 201 may further include a first bias auxiliary structure layer FBS1 located in the first conductive layer and the first bias auxiliary structure layer FBS1 is electrically connected with the first bias structure layer BS1. An orthographic projection of the first bias structure layer BS1 on the base substrate is overlapped with an orthographic projection of the first bias auxiliary structure layer FBS1 on the base substrate. In an exemplary implementation, the first bias auxiliary structure layer FBS1 may be electrically connected with the first bias structure layer BS1 through a via.

In an exemplary implementation, as shown in FIG. 1e, FIG. 1e is a schematic diagram of a planar structure of a second conductive layer in FIG. 1b (the M1 position in FIG. 1a), the first bias unit 201 may further include multiple first bias bridge structures QBS1 located in the second conductive layer. The multiple first bias bridge structures QBS1 extend along the first direction X, are arranged at intervals along the second direction Y, and are electrically connected with the first bias structure layer BS1 and the first bias auxiliary structure layer FBS1. In an exemplary implementation, the multiple first bias bridge structures QBS1 may be electrically connected with the first bias auxiliary structure layer FBS1 and the first bias structure layer BS1 through vias.

In an exemplary implementation, as shown in FIG. 1b, FIG. 1d and FIG. 1e, the first bias structure layer BS1 and the first bias auxiliary structure layer FBS1 are provided with multiple first hollow regions LK1, so that the first bias unit 201 forms a grid-like structure. An orthographic projection of the multiple fourth scan fan-out lines FG41 on the base substrate is not overlapped with an orthographic projection of the multiple first bias bridge structures QBS1 on the base substrate, and the multiple fourth scan fan-out lines FG41 respectively extend to the third drive fan-out region FG3 along the first direction X through intervals between the multiple first bias bridge structures QBS1, so as to avoid a short circuit between the first bias bridge structures QBS1 and the multiple fourth scan fan-out lines FG41.

In an exemplary implementation, the orthographic projection of the multiple first bias bridge structures QBS1 on the base substrate is not overlapped with an orthographic projection of the multiple first hollow regions LK1 on the base substrate, so as to avoid the short circuit between the first bias bridge structures QBS1 and the multiple fourth scan fan-out lines FG41.

In an exemplary implementation, the first bias unit 201 is provided in a grid-like structure, which may reduce an overlap area between the first bias unit 201 and the fourth scan fan-out lines FG41, reduce an overlap capacitance, reduce signal crosstalk, and avoid generation of static electricity in large area during a manufacture process. In addition, compared with a tiled whole-surface structure, the grid-like structure can improve flexibility, and can avoid failure of the first bias unit 201 in providing a bias signal normally due to the tiled whole-surface structure being easily broken.

In an exemplary implementation, the first bias unit 201 includes a first bias structure layer BS1, multiple first bias bridge structures QBS1, and a first bias auxiliary structure layer FBS1 that are stacked, and a multilayer structure electrically interconnected can reduce resistance of the first bias unit 201 so that bias signals supplied to different positions of the sensing region 100 are as consistent as possible.

In an exemplary implementation, the multiple fourth scan fan-out lines FG41 respectively extend to the third drive fan-out region FG3 along the first direction X through the intervals between the multiple first bias bridge structures QBS1, and are respectively connected with the multiple third scan fan-out lines FG31, so as to avoid a short circuit between the multiple fourth scan fan-out lines FG41 and the multiple first bias bridge structures QBS1. In an embodiment of the present disclosure, the multiple scan signal lines SL are respectively connected with the multiple fourth scan fan-out lines FG41 through fan-out wires in the third drive fan-out region FG3 to be adapted to a structure in which a size of the first bias unit 201 along the second direction Y is greater than a size of the sensing region 100 along the second direction Y, and the multiple third scan fan-out lines FG31 are connected with the multiple first static discharge circuits ST1 through the multiple fourth scan fan-out lines FG41 to be adapted to that a size of the first anti-static unit 301 along the second direction Y being greater than the size of the sensing region 100 along the second direction Y. A solution provided by an embodiment of the present disclosure may be applied to a sensing substrate with small pixels and high PPI, the PPI of the sensing region 100 is increased, the total quantity of pixels is increased, and the scan signal lines SL in the sensing region 100 are connected with the first anti-static unit 301 through the fan-out wires of the fan-out region, so that it is possible to be adapted to a structure in which the size of the first anti-static unit 301 along the second direction Y is greater than the size of the sensing region 100 along the second direction Y.

In an exemplary implementation, as shown in FIG. 1a, the fan-out region may further include a first drive fan-out region FG1 and a second drive fan-out region FG2. The anti-static element 300 may further include a second anti-static unit 302. The second drive fan-out region FG2 is on a side of a first side D1 away from a second side D2, the second anti-static unit 302 is on a side of the second drive fan-out region FG2 away from the sensing region 100, the first drive fan-out region FG1 is on a side of the second anti-static unit 302 away from the second drive fan-out region FG2, the drive port 500 is on a side of the first drive fan-out region FG1 away from the sensing region 100, and the second anti-static unit 302 is electrically connected with fan-out wires in the first drive fan-out region FG1 and fan-out wires in the second drive fan-out region FG2. One ends of the fan-out wires in the first drive fan-out region G1 are electrically connected with the multiple scan signal lines SL in the sensing region 100 through the fan-out wires in the second drive fan-out region FG2, and the other ends of the fan-out wires in the first drive fan-out region G1 are electrically connected with the drive port 500.

In an exemplary implementation, the second anti-static unit 302 may be configured to release static electricity of the first drive fan-out region FG1, the second drive fan-out region FG2, and the sensing region 100.

In an exemplary implementation, as shown in FIG. 1a, a size of a side of the second drive fan-out region FG2 close to the first drive fan-out region FG1 along the second direction Y is greater than a size of a side of the second drive fan-out region FG2 close to the sensing region 100 along the second direction Y. A size of a side of the first drive fan-out region FG1 away from the second drive fan-out region FD2 along the second direction Y is less than a size of a side of the first drive fan-out region close to the second drive fan-out region FD2 along the second direction Y.

In an exemplary implementation, in the case where the area of the sensing region 100 is correspondingly decreased as the total quantity of pixels in the sensing region 100 is unchanged and a single pixel becomes smaller to increase the PPI. Since the total quantity of pixel rows is not changed, the anti-static element 300 becomes smaller as the sensing region 100 becomes smaller, an anti-static capability of the anti-static element 300 will decrease, thus it is necessary to connect the multiple scan signal lines SL in the sensing region with the second anti-static unit 302 through the fan-out wires in the second drive fan-out region FG2 to be adapted to a high PPI sensing substrate. In the other case where the area of the sensing region 100 is unchanged and the pixels become smaller and the PPI is increased, so a total quantity of pixels will be increased correspondingly. As the total quantity of pixels is increased, the quantity of pixel rows is increased and the quantity of scan signal lines SL in the sensing region 100 is increased. Therefore, it is necessary to increase a size of the second anti-static unit 302 along the second direction Y. Therefore, it is necessary to configure such that fan-out wires in the second drive fan-out region FG2 connect the multiple scan signal lines SL in the sensing region 100 with the second anti-static unit 302 to be adapted to a high PPI sensing substrate.

In an exemplary implementation, as shown in FIG. 1a, FIG. 1f to FIG. 1h, FIG. 1f is a schematic partial enlarged view of M3 position in FIG. 1a, FIG. 1g is a schematic partial enlarged view of M4 position in FIG. 1a, and FIG. 1h is a schematic partial enlarged view of M5 position in FIG. 1a, the sensing substrate may further include a first power supply connection line VL1 and a second power supply connection line VL2 located in the second conductive layer, and a third power supply connection line VL3 located in the first conductive layer. The second anti-static unit 302 may include multiple second static discharge circuits ST2 arranged at intervals along the second direction Y. In a plane parallel to the sensing substrate, the first power supply connection line VL1 and the second power supply connection line VL2 extend along the second direction Y, the third power supply connection line VL3 extends along the first direction X, and the sensing region 100 may further include a third side D3 and a fourth side D4 disposed opposite to each other along the second direction Y.

The first power supply connection line VL1 is on a side of the second anti-static unit 302 away from the sensing region 100 and is electrically connected with the multiple second static discharge circuits ST2 in the second anti-static unit 302.

The second power supply connection line VL2 is on a side of the second anti-static unit 302 away from the sensing region 100 and is electrically connected with the multiple first static discharge circuits ST1 in the second anti-static unit 302.

A third power supply connection line VL3 is on a side of the third side D3 away from the fourth side D4, and two ends of the third power supply connection line VL3 are electrically connected with the first power supply connection line VL1 and the second power supply connection line VL2 respectively.

In an exemplary implementation, as shown in FIG. 1a, the sensing substrate may further include a fourth power supply connection line VL4 and a fifth power supply connection line VL5 located in the first conductive layer. On the second direction Y, the fourth power supply connection line VLA and the fifth power supply connection line VL5 are on two sides of the first drive fan-out region FG1 and the first power supply connection line VL1. On the first direction X, one end of the fourth power supply connection line VL4 is electrically connected with the first power supply connection line VL1, the other end of the fourth power supply connection line VL4 is connected with the drive port 500, one end of the fifth power supply connection line VL5 is electrically connected with the third power supply connection line VL3, and the other end of the fifth power supply connection line VL5 is connected with the drive port 500. In an exemplary implementation, shapes of the fourth power supply connection line VL4 and the fifth power supply connection line VL5 are consistent with an edge shape of the adjacent first drive fan-out region FG1. In an exemplary implementation, the fourth power supply connection line VL4 and the first power supply connection line VL1 may be connected through a via and the fifth power supply connection line VL5 and the third power supply connection line VL3 may be of an integrally formed structure.

In an exemplary implementation, the drive port 500 may be connected with a gate integrated circuit (Gate IC) of an external circuit, the gate integrated circuit transmits a scan signal to the scan signal lines SL through the drive port 500, and provides a power supply signal to the fourth power supply connection line VL4 and the fifth power supply connection line VL5 through the drive port 500. In an exemplary implementation, the first drive fan-out region FG1 connects multiple wires of the fourth drive fan-out region FG4 with the drive port 500 in a fan-out wiring manner. In an exemplary implementation, the drive port 500 may be a COF (full name Chip On Film) port.

In an exemplary implementation, as shown in FIG. 1f and FIG. 1g, the first conductive layer may further include multiple first scan fan-out lines FG11 located in the first drive fan-out region FG1, and multiple second scan fan-out lines FG21 located in the second drive fan-out region FG2. The multiple second scan fan-out lines FG21 are configured to be connected with the multiple scan signal lines SL, and the multiple first scan fan-out lines FG11 are configured to connect the multiple second scan fan-out lines FG21 with the drive port 500.

In an exemplary implementation, the multiple scan signal lines SL are respectively connected with the multiple first scan fan-out lines FG11 through the multiple fan-out wires in the second drive fan-out region FG2 to be adapted to that the size of the second anti-static unit 302 along the second direction Y is greater than the size of the sensing region 100 along the second direction Y. A solution provided by an embodiment of the present disclosure may be applied to a sensing substrate with small pixels and high PPI, the PPI of the sensing region 100 is increased, the total quantity of pixels is increased, the scan signal lines SL in the sensing region 100 are connected with the second anti-static unit 302 through the fan-out wires in the fan-out region, which can be adapted to a structure in which the size of the second anti-static unit 302 along the second direction Y is greater than the size of the sensing region 100 along the second direction Y. In an exemplary implementation, the second drive fan-out region FG2 may serve as a second anti-static fan-out region FS2.

In an exemplary implementation, as shown in FIG. 1a, the sensing substrate may further include a read port 400, the sensing region 100 may further include a third side D3 and a fourth side D4 disposed opposite to each other along the second direction Y, the fan-out region may further include a first data fan-out region FD1 and a second data fan-out region FD2, and the bias element 200 may further include a second bias unit 202. On the second direction Y, the second data fan-out region FD2 is on a side of the fourth side D4 away from the third side D3, the first data fan-out region FD1 is on a side of the second data fan-out region FD2 away from the sensing region 100, the second bias unit 202 is between the first data fan-out region FD1 and the second data fan-out region FD2, and the read port 400 is on a side of the first data fan-out region FD1 away from the sensing region 100. One end(s) of fan-out wire(s) in the first data fan-out region FD1 is electrically connected with at least part of the signal wires in the sensing region 100 through fan-out wires in the second data fan-out region FD2, and the other end(s) of the fan-out wire(s) in the first data fan-out region FD1 are electrically connected with the read port 400.

In an exemplary implementation, multiple signal wires in the sensing region 100 generally includes multiple columns of data signal lines DL, in the case where the area of the sensing region 100 is correspondingly decreased as the total quantity of pixels in the sensing region 100 is unchanged and a single pixel becomes smaller to increase the PPI. Since the total quantity of pixel columns is not changed, it is necessary to lead out the multiple data signal lines DL in the sensing region 100 through the fan-out wires of the first data fan-out region FD1 and the second data fan-out region FD2 to be adapted to a high PPI sensing substrate. In the other case where the area of the sensing region 100 is unchanged and the pixels become smaller and the PPI is increased, so the total quantity of pixels will be increased correspondingly. As the total quantity of pixels is increased, the quantity of pixel columns is increased and the quantity of data signal lines DL in the sensing region 100 is increased. Therefore, it is also necessary to configure such that fan-out wires of the first data fan-out region FD1 and the second data fan-out region FD2 lead out the multiple data signal lines DL in the sensing region 100 to be adapted to a high PPI sensing substrate.

In an exemplary implementation, as shown in FIG. 1a and FIG. 1b, the multiple signal wires in the sensing region 100 may include multiple data signal lines DL located in the second conductive layer, the multiple data signal lines DL extend along the second direction Y and are arranged at intervals along the first direction X. The second bias unit 202 may include a second bias structure layer BS2.

The second conductive layer may further include multiple first data fan-out lines FD11 located in the first data fan-out region FD1, and multiple second data fan-out lines FD21 located in the second data fan-out region FD2. The multiple second data fan-out lines FD21 are configured to be connected with the multiple data signal lines DL, the multiple first data fan-out lines FD11 are configured to connect the multiple second data fan-out lines FD21 with the read port 400.

The first electrode layer may further include a second bias structure layer BS2 and the second bias structure layer BS2 is electrically connected with the first bias structure layer BS1. In an exemplary implementation, the second bias structure layer BS2 and the first bias structure layer BS1 may be of an integrally formed structure.

In an exemplary implementation, as shown in FIG. 1b, FIG. 1d and FIG. 1e, the second bias unit 202 may further include a second bias auxiliary structure layer FBS2 located in the first conductive layer and multiple second bias bridge structures QBS2 located in the second conductive layer.

The second bias auxiliary structure layer FBS2 is electrically connected with the second bias structure layer BS2. An orthographic projection of the second bias structure layer BS2 on the base substrate is overlapped with an orthographic projection of the second bias auxiliary structure layer FBS2 on the base substrate.

The multiple second bias bridge structures QBS2 extend along the second direction Y, are arranged at intervals along the first direction X, and are electrically connected with the second bias structure layer BS2 and the second bias auxiliary structure layer FBS2.

The second bias structure layer BS2 and the second bias auxiliary structure layer FBS2 are provided with multiple second hollow regions LK2, so that the second bias unit 202 forms a grid-like structure. An orthographic projection of the multiple first data fan-out lines FG11 on the base substrate is not overlapped with an orthographic projection of the multiple second bias bridge structures QBS2 on the base substrate, so as to avoid a short circuit between the second bias bridge structures QBS2 and the multiple first data fan-out lines FG11. The multiple first data fan-out lines FG11 respectively extend to the second drive fan-out region FD2 along the second direction Y through the intervals between the multiple second bias bridge structures QBS2.

In an exemplary implementation, an orthographic projection of a second bias bridge structure QBS2 on the base substrate is not overlapped with an orthographic projection of the multiple second hollow regions LK2 on the base substrate to avoid a short circuit between the second bias bridge structure QBS2 and the multiple first data fan-out lines FG11. In an exemplary implementation, the multiple second bias bridge structures QBS2 may be electrically connected with the second bias structure layer BS2 and the second bias auxiliary structure layer FBS2 through vias.

In an exemplary implementation, the second bias unit 202 is provided in a grid-like structure, which may reduce an overlap area between the second bias unit 202 and the multiple first data fan-out lines FG11, reduce an overlap capacitance, reduce signal crosstalk, and avoid generation of static electricity in large area during a manufacture process. In addition, compared with a tiled whole-surface structure, the grid-like structure can improve flexibility, and can avoid failure of the second bias unit 202 in providing a bias signal normally due to the tiled whole-surface structure being easily broken.

In an exemplary implementation, the second bias unit 202 includes a second bias structure layer BS2, multiple second bias bridge structures QBS2, and a second bias auxiliary structure layer FBS2 that are stacked, and a multilayer structure electrically interconnected can reduce the resistance of the second bias unit 202 so that bias signals supplied to different positions of the sensing region 100 are as consistent as possible.

In an exemplary implementation, as shown in FIG. 1a, the sensing substrate may further include a first bias wire B1 and a second bias wire B2 located at the second conductive layer. On the first direction X, the first bias wire B1 and the second bias wire B2 are on two sides of the second bias unit 202 and the first data fan-out region FD1. On the second direction Y, the first bias wire B1 and the second bias wire B2 are on a side of the second bias unit 202 away from the sensing region 100, each of the first bias wire B1 and the second bias wire B2 has one end connected with the second bias unit 202 and the other end connected with the read port 400.

In an exemplary implementation, the read port 400 may be connected with a read integrated circuit (ROIC) of an external circuit, the read integrated circuit may provide bias signals to the first bias wire B1 and the second bias wire B2 through the read port 400, and read data signals from data signal lines 30. In an exemplary implementation, a quantity of read ports 400 may be provided according to a quantity of data signal lines DL in the sensing region 100. One read port 400 may be provided in a case where a quantity of channels of one read port 400 can satisfy multiple data signal lines DL, and multiple read ports may be provided in a case where a quantity of channels of one read port 400 cannot satisfy multiple data signal lines. As shown in FIG. 1a, a quantity of read ports 400 is two, two first data fan-out regions FD1 corresponding to the two read ports 400 may be provided, and one second data fan-out region FD2 may be provided. In an exemplary implementation, the read port 400 may be a COF (full name Chip On Film) port.

In an exemplary implementation, as shown in FIG. 1a, FIG. 1g to FIG. 1k, the bias element 200 may further include a third bias unit 203 located on a side of the third side D3 away from the fourth side D4. On the second direction Y, the third bias unit 203 is between the sensing region 100 and the third power supply connection line VL3, and the third bias unit 203 may include a third bias structure layer BS3 located at the first electrode layer, a third bias auxiliary structure layer FBS3 located at the first conductive layer, and multiple third bias bridge structures QBS3 located at the second conductive layer. As shown in FIG. 1j and FIG. 1k, FIG. 1j is a schematic diagram of a planar structure of a third bias auxiliary structure layer FBS3 in FIG. 1i (M6 position) and FIG. 1k is a schematic diagram of a planar structure of multiple third bias bridge structures QBS3 in FIG. 1i (the M6 position).

The third bias auxiliary structure layer FBS3 is electrically connected with the third bias structure layer BS3, and the third bias structure layer BS3 is electrically connected with the first bias structure layer BS1. An orthographic projection of the third bias structure layer BS3 on the base substrate is overlapped with an orthographic projection of the third bias auxiliary structure layer FBS3 on the base substrate.

The multiple third bias bridge structures QBS3 extend along the second direction Y, are arranged at intervals along the first direction X, and are electrically connected with the third bias structure layer BS3 and the third bias auxiliary structure layer FBS3.

In an exemplary implementation, the third bias auxiliary structure layer FBS3 and the third bias structure layer BS3 may be electrically connected through a via, the third bias auxiliary structure layer BS3 and the first bias auxiliary structure layer FBS1 may be of an integrally formed structure, and the multiple third bias bridge structures QBS3 may be electrically connected with the third bias structure layer BS3 and the third bias auxiliary structure layer FBS3 through vias.

In an exemplary implementation, the third bias structure layer BS3 and the third bias auxiliary structure layer FBS3 are provided with multiple third hollow regions LK3, so that the third bias unit 203 forms a grid-like structure. In an exemplary implementation, the third bias unit 203 is provided in a grid-like structure in such a manner as to be as consistent as possible with the second bias unit 202 and the first bias unit 201, so that the bias signal provided to the sensing region 100 through the bias element 200 is as consistent as possible.

In an exemplary implementation, the third bias unit 203 includes a third bias structure layer BS3, multiple third bias bridge structures QBS3, and a third bias auxiliary structure layer FBS3 that are stacked, and the multi-layer structure may reduce a resistance of the third bias unit 203, so that bias signals provided to different positions of the sensing region 100 are as consistent as possible.

In an exemplary implementation, the first bias structure layer BS1, the second bias structure layer BS2, and the third bias structure layer BS3 at the first electrode layer may be of an integrally formed structure. The first bias auxiliary structure layer FBS1, the second bias auxiliary structure layer FBS2, and the third bias auxiliary structure layer FBS3 at the first conductive layer may be of an integrally formed structure, so that the first bias unit 201, the second bias unit 202, and the third bias unit 203 are connected to each other, and the bias signals provided to different positions of the sensing region 100 may be as consistent as possible.

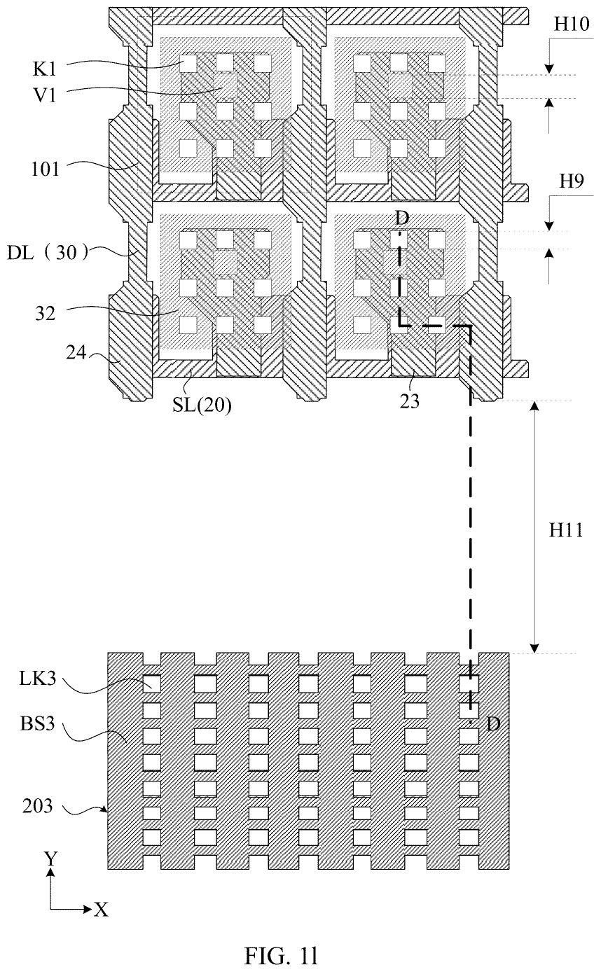

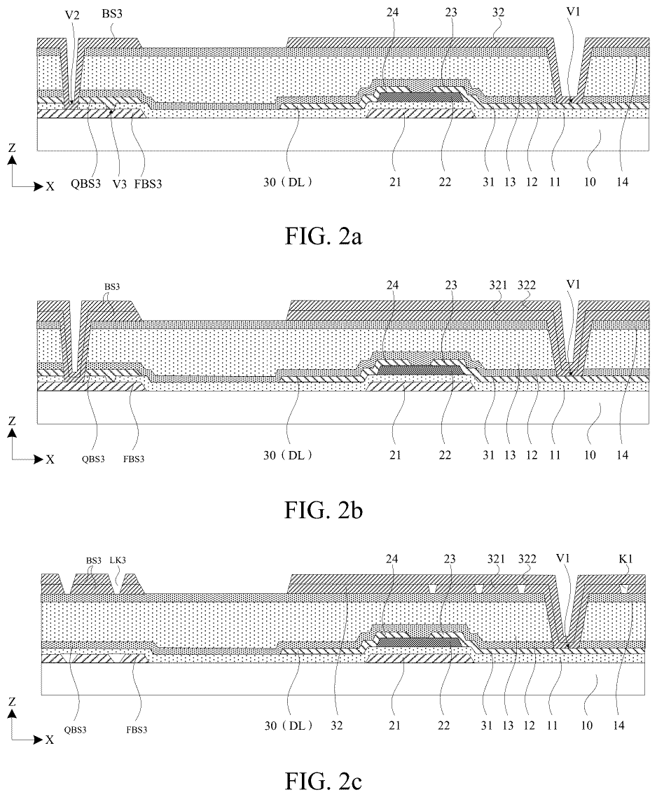

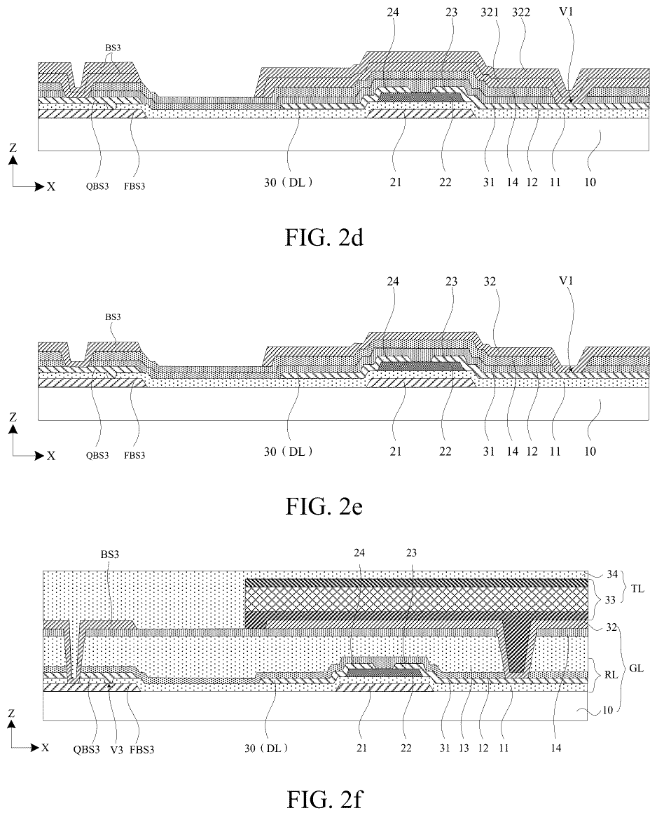

In an exemplary implementation, as shown in FIG. 1a, FIG. 1i, and FIG. 2a, FIG. 2a is a schematic view of a cross-sectional structure along position C-C in FIG. 1i, multiple signal wires in the sensing region 100 may include multiple data signal lines DL (i.e., data signal lines 30) located at the second conductive layer, the multiple data signal lines DL extend along the second direction Y and are arranged at intervals along the first direction X. Multiple data signal lines DL and multiple scan signal lines SL (i.e., scan signal lines 20) define multiple pixel areas 101. At least part of the pixel areas 101 is provided with a thin film transistor and a first electrode 32. The first electrode 32 is at the first electrode layer, and an orthographic projection of the first electrode 32 on the base substrate is overlapped with an orthographic projection of a corresponding thin film transistor on the base substrate.

In an exemplary implementation, as shown in FIG. 2a, the thin film transistor may include a gate electrode 21 located at the first conductive layer, a source electrode 23 and a drain electrode 24 located at the second conductive layer, and an active layer 22 located between the first conductive layer and the second conductive layer. The source electrode 23 is electrically connected with a corresponding first electrode 32, and the drain electrode 24 and a corresponding data signal line DL are of an integrally formed structure.

In an exemplary implementation, as shown in FIG. 1i, on a plane parallel to the sensing substrate, a size H1 of a pixel area 101 along the first direction X may be 10 microns to 20 microns, and a size H2 of a pixel area 101 along the second direction Y may be 10 microns to 20 microns. For example, the size H1 of the pixel area 101 along the first direction X may be 15 microns and the size H2 of the pixel area 101 along the second direction Y may be 15 microns. In an exemplary implementation, as shown in FIG. 1i, in a plane parallel to the sensing substrate, in a same pixel area 101, on the first direction X, a size H3 of a data signal line DL (30) (i.e., a line width of the data signal line DL) may be 1 micron to 2 microns, a distance H4 between the data signal line 30 and an opposite side surface of a corresponding first electrode 32 is 0.9 micron to 1.9 microns, and a distance H5 between the drain electrode 24 and an opposite side surface of the source electrode 23 (i.e., a channel length of the thin film transistor) is 1.5 microns to 2.5 microns. On the second direction Y, a size H6 of the scan signal line SL (20) (i.e., a line width of the scan signal line 20) is 1 micron to 2 microns, a distance H7 between the scan signal line SL and an opposite side surface of a corresponding first electrode 32 is 0.8 micron to 1.8 microns, and a size H8 of the active layer 22 (i.e., a channel width of the thin film transistor) is 2.5 microns to 3.5 microns. For example, in a same pixel area 101, on the first direction X, the size H3 of the data signal line DL (30) (i.e., the line width of the data signal line DL) may be 1.5 microns, the distance H4 between the data signal line 30 and the opposite side surface of the corresponding first electrode 32 may be 1.4 microns, and the distance H5 between the drain electrode 24 and the opposite side surface of the source electrode 23 (i.e., the channel length of the thin film transistor) may be 2 microns. On the second direction Y, the size H6 of the scan signal line SL (20) (i.e., the line width of the scan signal line 20) is 1.5 microns, the distance H7 between the scan signal line SL and the opposite side surface of the corresponding first electrode 32 is 1.3 microns, and the size H8 of the active layer 22 (i.e., the channel width of the thin film transistor) is 3 microns.

In an exemplary implementation, as shown in FIG. 1i and FIG. 2a, the sensing substrate may further include an insulation layer located between the second conductive layer and the first electrode layer in a direction perpendicular to a plane where the sensing substrate is located, and multiple first vias V1 are provided on the insulation layer. The second conductive layer is further provided with multiple first switch electrodes 31, the multiple first switch electrodes 31 are respectively integrally formed with the source electrodes 23 of corresponding thin film transistors, and the multiple first electrodes 32 are respectively electrically connected with corresponding first switch electrodes 31 through the multiple first vias V1. An orthographic projection of the multiple first vias V1 on the base substrate is respectively overlapped with an orthographic projection of the multiple first electrodes 32 on the base substrate and an orthographic projection of the multiple first switch electrodes 31 on the base substrate.

In the exemplary implementation, the first conductive layer further includes a gate electrode 21 of the thin film transistor, the gate electrode 21 and a corresponding scan signal line SL are integrally formed. A shape of each first switch electrode 31 is polygonal, and the first switch electrode 31 is on a side of a corresponding source electrode 23 on the second direction Y. A size of a side of the first switch electrode 31 close to the corresponding source electrode 23 along the first direction X is less than a size of a side of the first switch electrode 31 away from the corresponding source electrode 23 along the first direction X. An orthographic projection of a side of the first switch electrode 31 connected with the corresponding source electrode 23 on the base substrate 10 is at least partially overlapped with an orthographic projection of a corresponding gate electrode 21 on the base substrate 10, and an end of the first switch electrode 31 away from the corresponding source electrode 21 is electrically connected with a corresponding first electrode 32 through a first via.

In an exemplary implementation, as shown in FIG. 2a, the third bias structure layer BS3 may be electrically connected with the third bias auxiliary structure layer FBS3 and the third bias bridge structure QBS3 through a second via V2, and the third bias bridge structure QBS3 may be electrically connected with the third bias auxiliary structure layer FBS3 through a third via V3.

In an exemplary implementation, as shown in FIG. 2a, the first electrode 32 may be a single layer of transparent conductive material, for example, as shown in FIG. 2a, the first electrode 32 may be made of a single layer of indium tin oxide (ITO) material. Indium tin oxide (ITO) is a transparent conductive material and the first electrode layer 32 of the single layer of transparent conductive material may improve light transmittance and reduce light shielding.

In an exemplary implementation, as shown in FIG. 2b, FIG. 2b is another schematic view of a cross-sectional structure along position C-C in FIG. 1i, in a direction perpendicular to a plane where the sensing substrate is located, at least a part of the first electrode 32 may include a first functional layer 321 and a second functional layer 322. The second functional layer 322 is on a side of the first functional layer 321 away from the base substrate 10, and an orthographic projection of the first functional layer 321 on the base substrate is overlapped with an orthographic projection of a corresponding second functional layer 322 on the base substrate. In an exemplary implementation, the first electrode 32 is provided to be in a two-layer structure to improve conductivity.

In an exemplary implementation, as shown in FIG. 1L and FIG. 2c, FIG. 1L is another schematic partial enlarged view of M6 position in FIG. 1a, and FIG. 2c is a schematic view of a cross-sectional structure along position D-D in FIG. 1L. Multiple openings K1 are provided on the first functional layer 321, and in a plane parallel to the sensing substrate, an aperture size H9 of an opening K1 is 1.5 microns to 5 microns. For example, in the plane parallel to the sensing substrate, the aperture size H9 of the opening K1 is 2 microns.

In an exemplary implementation, as shown in FIG. 2a to FIG. 2c, in a direction perpendicular to a plane where the sensing substrate is located, the insulation layer may include a second insulation layer 12, a planarization layer 13 and a third insulation layer 14 that are sequentially disposed on a side of the second conductive layer away from the base substrate. The planarization layer 13 may be configured to planarize a film height difference caused by the thin film transistors and avoid process defects caused by excessive climbing of a subsequent film during deposition. Optionally, as shown in FIG. 2d and FIG. 2e, FIG. 2d and FIG. 2e are other two schematic views of a cross-sectional structure along position C-C in FIG. 1i, the insulation layer may include a second insulation layer 12 and a third insulation layer 14 disposed on the side of the second conductive layer away from the base substrate, and as no planarization layer is provided, it is possible to simplify a process flow of manufacturing the sensing substrate, reduce a manufacture cost and reduce a thickness of the sensing substrate.

In an exemplary implementation, as shown in FIG. 1L, in a plane parallel to the sensing substrate, an aperture size H10 of a first via V1 is 1.5 microns to 2.5 microns. For example, in a plane parallel to the sensing substrate. the aperture size of the first via V1 may be 2 microns.

In an exemplary implementation, as shown in FIG. 1L, in a plane parallel to the sensing substrate, a distance H11 between the bias element 200 and the sensing region 100 is greater than or equal to 8.6 mm. A certain distance H11 is provided between the bias element 200 and the sensing region 100, which can prevent manufacture of a detection layer (the detection layer may include a new sensitive material) in the sensing region 100 of the sensing substrate from causing a short circuit on the bias element 200 due to manufacture of a second electrode in the detection layer being too close.

The sensing substrate provided by the embodiment of the present disclosure may be configured to verify a new photoelectric sensitive material, or may be configured to manufacture a sensing device (e.g., to manufacture a detector, a sensor). Compared with a silicon-base sensing substrate, a manufacture cost is greatly reduced on a condition of adapting to a high PPI.

An embodiment of the present disclosure further provides a sensing device, as shown in FIG. 2f, the sensing substrate may include a detection layer TL and a sensing substrate GL described in any of the above embodiments. The sensing substrate GL may include a base substrate 10 and a read layer RL disposed on the base substrate, and the detection layer TL is disposed on a side of the read layer away from the base substrate 10.

In an exemplary implementation, as shown in FIG. 1a and FIG. 2f, on a plane parallel to the sensing substrate, the sensing substrate may include a sensing region 100 and the sensing region 100 is provided with multiple first electrodes 32 electrically connected with the read layer RL. In the direction Z perpendicular to a plane where the sensing substrate is located, the multiple first electrodes 32 are on a side of the read layer RL away from the base substrate 10, and the detection layer TL includes a photoelectric conversion layer 33 disposed on a side of the first electrodes 32 away from the base substrate 10, and a second electrode layer 34 disposed on a side of the photoelectric conversion layer 33 away from the base substrate 10.

In an exemplary implementation, as shown in FIG. 1a and FIG. 2f, on a plane parallel to the sensing substrate, a bias element 200 is provided on at least one side of the sensing region 100 and the bias element 200 is electrically connected with the second electrode layer 34 and configured to supply a bias voltage to the second electrode layer 34. In an exemplary implementation, FIG. 2f may be a sensing device after a detection layer is manufactured on the sensing substrate of FIG. 2a.

Exemplary description is made below through a manufacture process of a sensing substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacture process, the “thin film” may also be called a “layer”. If the “thin film” needs to be processed through the patterning process in the entire manufacture process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of A includes an orthographic projection of B” refers to that a boundary of the orthographic projection of B falls within a range of a boundary of the orthographic projection of A, or the boundary of the orthographic projection of A is overlapped with the boundary of the orthographic projection of B.

In an exemplary implementation, the manufacture process of the sensing substrate may include the following operations (two rows and two columns of pixels are taken as an example for illustration).

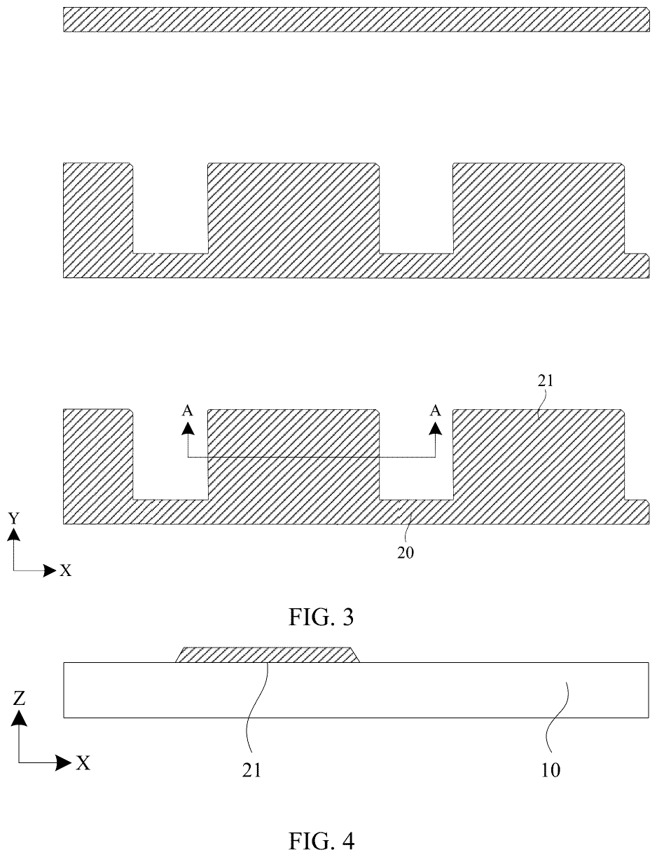

(1) A pattern of a first conductive layer is formed. In an exemplary implementation, forming the pattern of the first conductive layer may include depositing a first metal thin film on a base substrate and patterning the first metal thin film by a patterning process to form the pattern of the first conductive layer. The first conductive layer at least includes a scan signal line 20 and a gate electrode 21, as shown in FIG. 3 and FIG. 4. FIG. 4 is a cross-sectional view taken along A-A direction in FIG. 3.

In an exemplary embodiment, scan signal lines 20 may extend along a horizontal direction (a first direction X) and multiple scan signal lines 20 may be parallel to each other. A gate electrode 21 is provided in at least one identification pixel and the gate electrode 21 may be of an integral structure connected with the scan signal lines 20.

In an exemplary embodiment, the base substrate may be a hard substrate or a flexible substrate, such as a glass or a polyimide (PI). The first metal thin film may be made of a metal material, such as any one or more of silver (Ag), copper (Cu), aluminum (Al), titanium (Ti), and molybdenum (Mo), or an alloy material of the above metals, such as aluminum neodymium alloy (AlNd) or molybdenum niobium alloy (MoNb), and may be in a single-layer structure or multi-layer composite structure, such as Ti/Al/Ti.

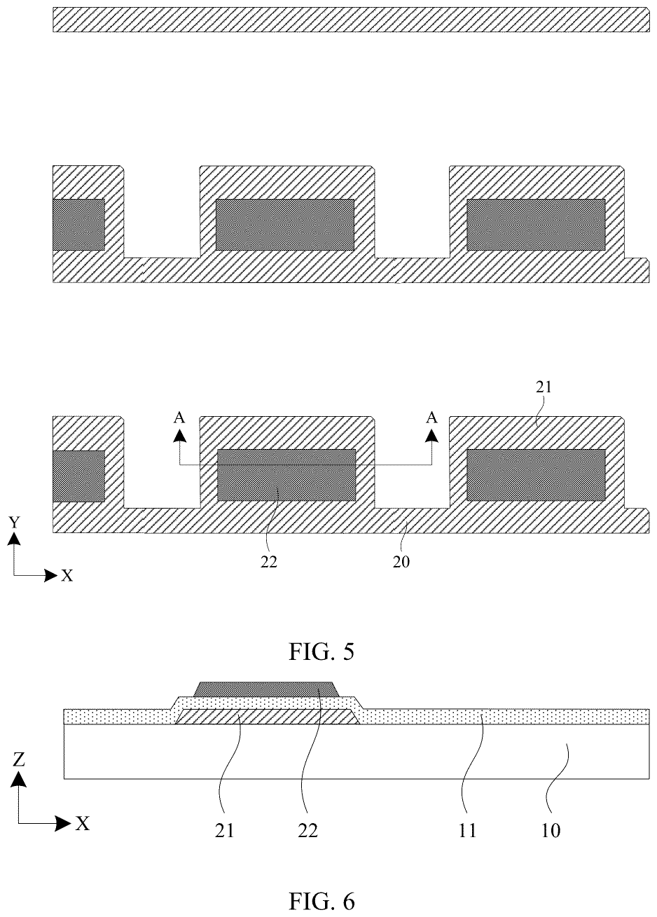

(2) A pattern of a semiconductor layer is formed. In an exemplary implementation, forming the pattern of the semiconductor layer may include: depositing sequentially a first insulation thin film and a semiconductor thin film on the base substrate on which the aforementioned patterns are formed, and patterning the semiconductor thin film through a patterning process to form a first insulation layer 11 that covers the pattern of the first conductive layer, and to form the pattern of the semiconductor layer disposed on the first insulation layer 11. The pattern of the semiconductor layer at least includes an active layer 22, as shown in FIG. 5 and FIG. 6, and FIG. 6 is a cross-sectional view taken along A-A direction in FIG. 5.

In an exemplary embodiment, the active layer 22 is disposed within at least one identification pixel and an orthographic projection of the active layer 22 on the base substrate is overlapped with an orthographic projection of the gate electrode 21 on the base substrate.

In an exemplary embodiment, the semiconductor thin film may be made of materials such as amorphous indium gallium zinc oxide (a-IGZO), zinc oxynitride (ZnON), indium zinc tin oxide (IZTO), amorphous silicon (a-Si), polysilicon (p-Si), hexathiophene, or polythiophene. That is, the present disclosure is applicable to transistors that are manufactured based on oxide technology, silicon technology or organic technology. The first insulation layer may be made of any one or more of Silicon Oxide (SiOₓ), Silicon Nitride (SiNₓ), and Silicon Oxynitride (SiON), and may be a single-layer, a multi-layer, or a composite layer. The first insulation layer may be referred to as a gate insulation (GI) layer.

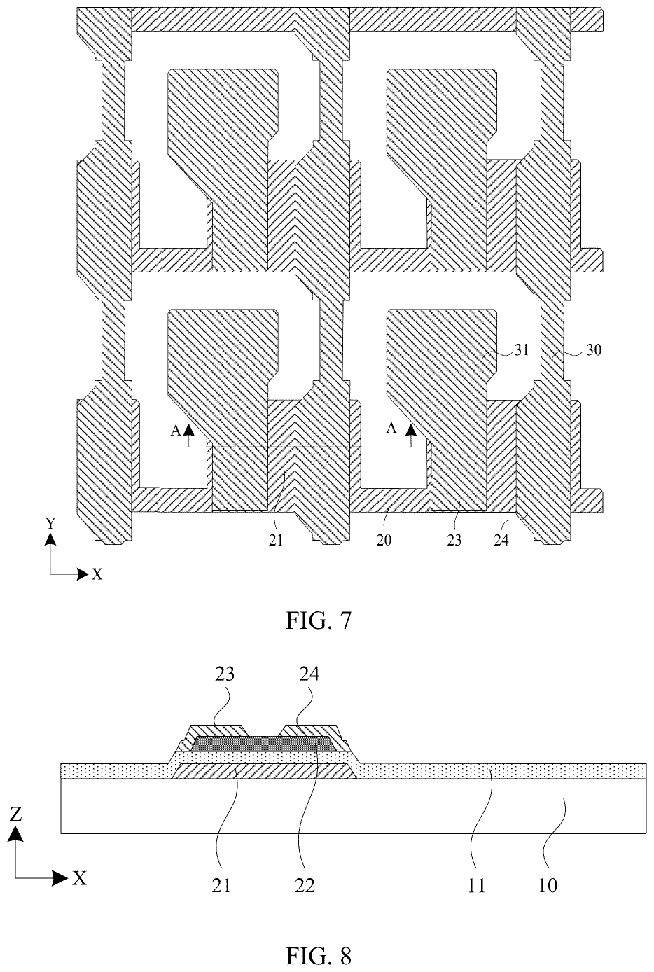

(3) A pattern of a second conductive layer is formed. In an exemplary implementation, forming the pattern of the second conductive layer may include depositing a second metal thin film on the base substrate on which the aforementioned patterns are formed, and patterning the second metal thin film by a patterning process to form the pattern of the second conductive layer. The second conductive layer includes a data signal line 30, a source electrode 23, a drain electrode 24, and a first switch electrode 31, as shown in FIG. 7 and FIG. 8, and FIG. 8 is a cross-sectional view taken along A-A direction in FIG. 7.

In an exemplary embodiment, the data signal lines 30 extend along a vertical direction (a second direction Y) and multiple data signal lines 30 are parallel to each other. The multiple scan signal lines 20 extending along the horizontal direction and the multiple data signal lines 30 extending along the vertical direction that are intersected with each other define multiple identification pixels arranged in an array.

In an exemplary embodiment, a source electrode 23, a drain electrode 24, and a first switch electrode 31 are provided in at least one identification pixel. The drain electrode 24 may be connected with the data signal line 30 to form an integral structure, the drain electrode 24 is provided oppositely to the source electrode 23, an active layer between the source electrode 23 and the drain electrode 24 forms a channel area, and the first switch electrode 31 is connected with the source electrode 23.

In an exemplary embodiment, the source electrode 23 and the first switch electrode 31 may be of an integral structure, i.e., the source electrode of the thin film transistor may be electrically connected with the negative electrode of the PIN junction photodiode through the first switch electrode 31.

In an exemplary embodiment, the second metal thin film may be made of a metal material, such as any one or more of silver (Ag), copper (Cu), aluminum (Al), titanium (Ti), and molybdenum (Mo), or an alloy material of the above metals, such as aluminum neodymium alloy (AlNd) or molybdenum niobium alloy (MoNb), and may be in a single-layer structure or multi-layer composite structure, such as Ti/Al/Ti.

Thus, a thin film transistor (TFT) used as a switch device in the sensing substrate is formed on the base substrate and the thin film transistor includes the gate electrode 21, a the n active layer 22, the source electrode 23, and the drain electrode 24.

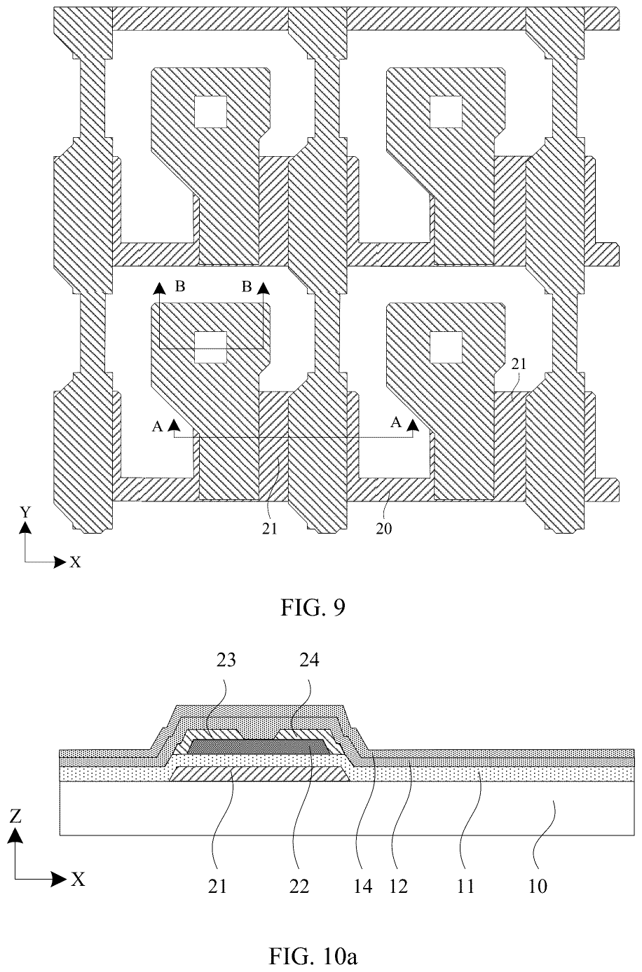

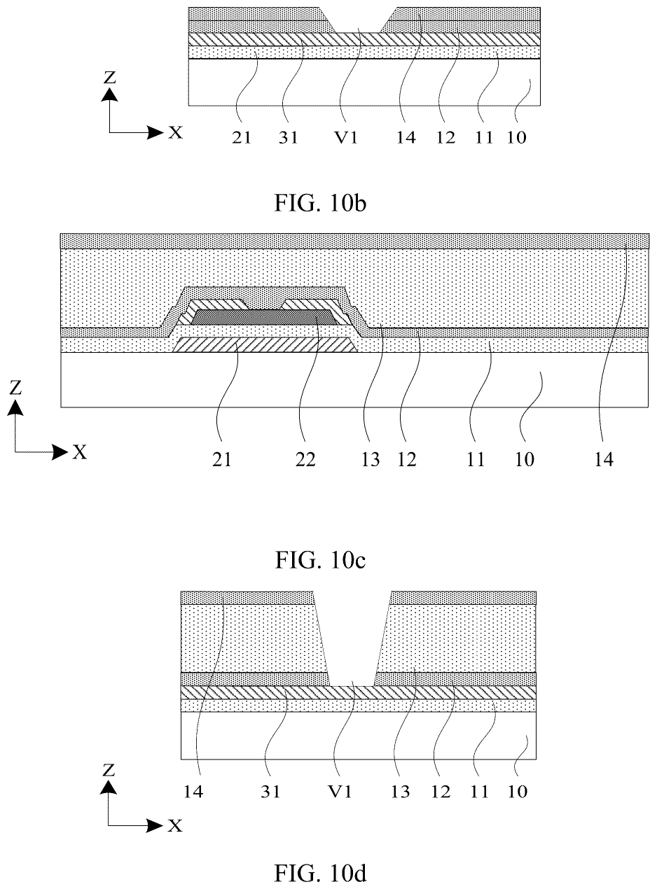

(4) Patterns of a second insulation layer and a third insulation layer are formed. In an exemplary implementation, forming the pattern of the second insulation layer may include depositing a second insulation thin film and a third insulation layer thin film on the base substrate on which the aforementioned patterns are formed, patterning the second insulation thin film and the third insulation layer thin film by a patterning process, to form a second insulation layer 12 that covers the pattern of the second conductive layer and a third insulation layer 14 disposed on the second insulation layer 12, a first via V1 is provided on the second insulation layer 12 and the third insulation layer 14, the first via V1 is located in an area where the first switch electrode 31 is located, the second insulation layer 12 and the third insulation layer 14 in the first via V1 are etched away, to expose a surface of the first switch electrode 31, as shown in FIG. 9, FIG. 10a and FIG. 10b. FIG. 10a is a cross-sectional view taken along A-A direction in FIG. 9, and FIG. 10b is a cross-sectional view taken along B-B direction in FIG. 9.

In an exemplary implementation, after deposition of the second insulation thin film and before deposition of the third insulation thin film, the process may include: coating a planarization layer thin film; patterning the second insulation thin film and the third insulation layer thin film by a patterning process may include: patterning the second insulation film, the planarization layer thin film and the third insulation layer film by a patterning process to form the second insulation layer 12 that covers the pattern of the second conductive layer, a planarization layer 13 disposed on the second insulation layer 12, and a third insulation layer 14 disposed on the planarization layer 13. The second insulation layer 12, the planarization layer 13, and the third insulation layer 14 in the first via VI are etched away to expose a surface of the first switch electrode 31, as shown in FIG. 10c and FIG. 10d. FIG. 10c is another cross-sectional view taken along A-A direction in FIG. 9, and FIG. 10d is another cross-sectional view taken along B-B direction in FIG. 9.

In an exemplary implementation, the planarization layer 13 is configured to planarize a film height difference caused by the thin film transistor and avoids process defects caused by excessive climbing of a subsequent film during deposition.

In an exemplary implementation, the planarization layer may be made of a resin material and the third insulation layer may be any one or more of silicon oxide (SiOₓ), silicon nitride (SiNₓ), and silicon oxynitride (SiON), and may be in a single layer, a multi-layer, or a composite layer.

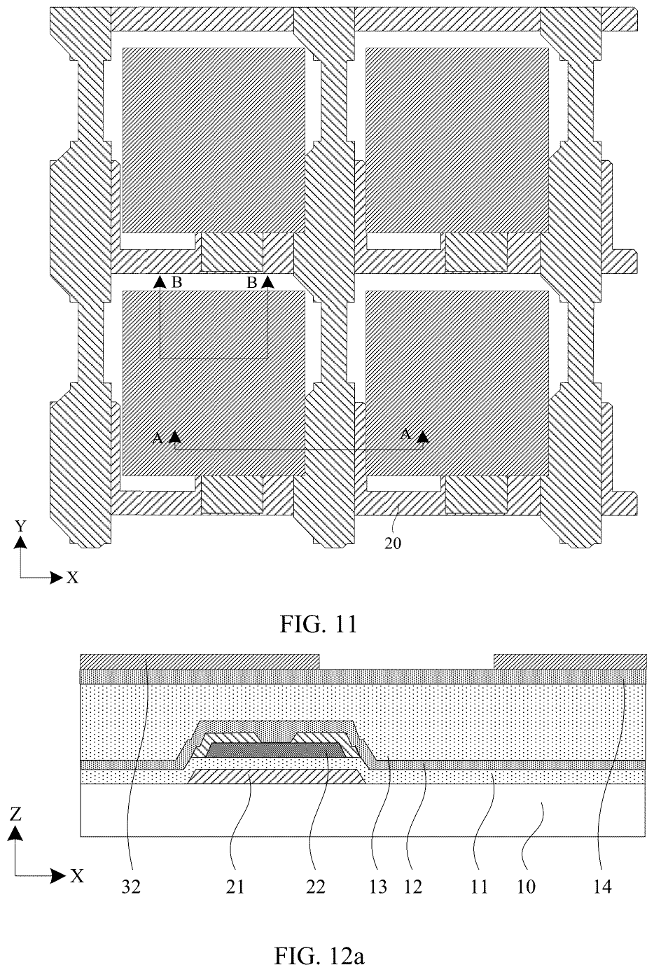

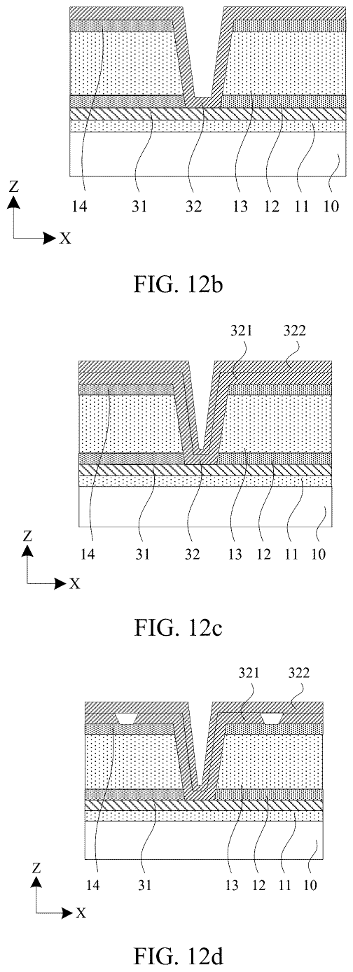

(5) A pattern of a first electrode is formed. In an exemplary implementation, forming the pattern of the first electrode may include depositing a first electrode conductive thin film on the base substrate on which the aforementioned patterns are formed, patterning the first electrode conductive thin film by a patterning process to from the pattern of the first electrode 32 on the third insulation layer 14, the first electrode 32 is electrically connected with the first switch electrode 31 through the first via V1, as shown in FIG. 11 to FIG. 12b. FIG. 12a is a cross-sectional view taken along A-A direction in FIG. 11, and FIG. 12b is a cross-sectional view taken along B-B direction in FIG. 11.

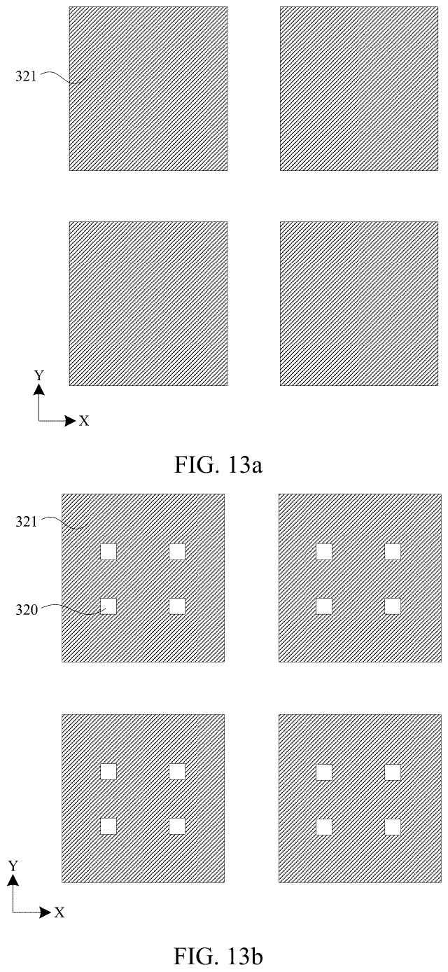

In an exemplary implementation, the first electrode 32 may be a single-layer transparent conductive thin film, for example, as shown in FIG. 12b, the first electrode 32 may be a layer of ITO conductive glass. In an exemplary implementation, the first electrode 32 may include two film layer structures including a first functional layer 321 and a second functional layer 322, as shown in FIG. 12c and FIG. 12d. FIG. 12c and FIG. 12d are two types of cross-sectional views taken along B-B direction in FIG. 11. In an exemplary implementation, the first electrode 32 is provided in a two-layer structure to improve conductivity. As shown in FIG. 12c, the first functional layer 321 of each pixel has a front-face-laid structure, and as shown in FIG. 12d, multiple open apertures 320 are provided on the first functional layer 321 of each pixel, and the open apertures 320 penetrate through the first functional layer 321 to improve light transmittance of the first electrode 32 while ensuring conductivity of the first electrode 32. As shown in FIG. 13a and FIG. 13b, FIG. 13a is a schematic diagram of a planar structure of a first functional layer 321 in FIG. 12c, and FIG. 13b shows a schematic diagram of a planar structure of a first functional layer 321 in FIG. 12d.

In an exemplary implementation, the first functional layer 321 may be made of a conductive metal and the second functional layer 322 may be made of indium tin oxide (ITO) or indium zinc oxide (IZO).

So far, a sensing substrate (the sensing substrate may be referred to as a backplane) is formed on the base substrate, and a thin film transistor (TFT) that serves as a switch device is included in the backplane. The thin film transistor includes a gate electrode 21, an active layer 22, a source electrode 23, and a drain electrode 24. An array formed by thin film transistors can serve as a read circuit of the sensing substrate, and the backplate further includes the first electrode 32 located on a side of the read circuit away from the base substrate. The detection layer may be made on the basis of the aforementioned backplate, and the structure of the backplate and the detection layer may form a sensor or verify a new photoelectric sensitive material of the detection layer.

In an exemplary implementation, a manufacture process for forming the detection layer on the sensing substrate may include the following operations.

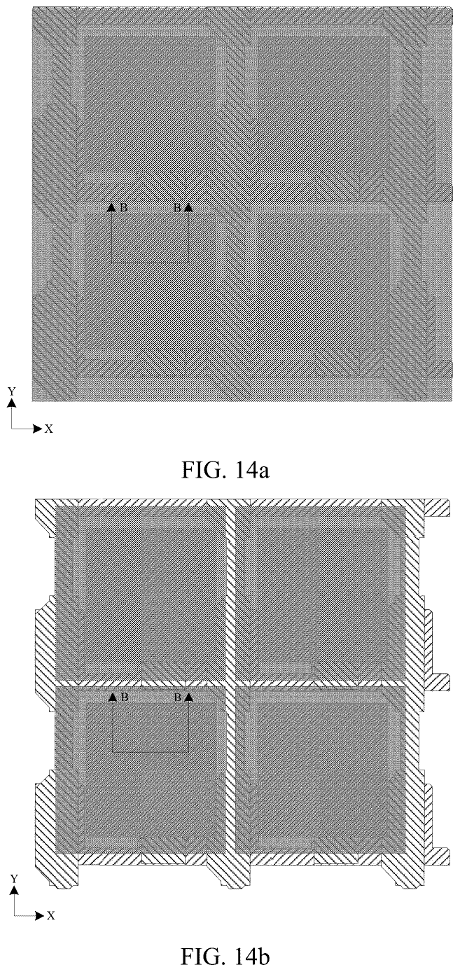

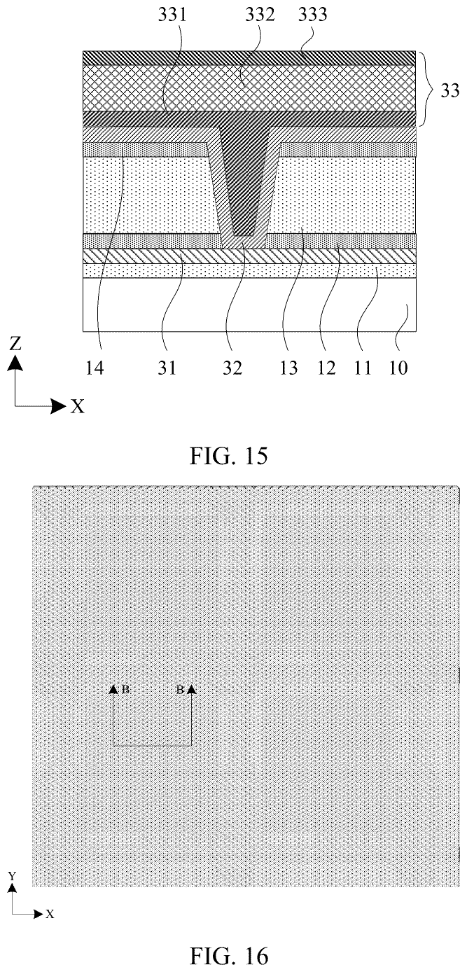

(6) A pattern of a photoelectric conversion layer is formed. In an exemplary implementation, forming the pattern of the photoelectric conversion layer may include depositing a photoelectric conversion thin film on the base substrate on which the aforementioned patterns are formed, patterning the photoelectric conversion thin film by a patterning process to form the pattern of the photoelectric conversion layer 33, the photoelectric conversion layer 33 is disposed on the first electrode 32 in the first via V1 and connected with the first electrode 32, as shown in FIG. 14a, FIG. 14b, and FIG. 15. FIG. 15 is a cross-sectional view taken along B-B direction in FIG. 14a and FIG. 14b.

In an exemplary embodiment, the photoelectric conversion layer 33 may include an electron transport layer (ETL) 331, a photoelectric sensitive material layer 332, and a hole transport layer (HTL) 333 that are sequentially disposed on the first electrode 32.

In an exemplary embodiment, an orthographic projection of the photoelectric conversion layer 33 on the base substrate is not overlapped with an orthographic projection of the thin film transistor on the base substrate.

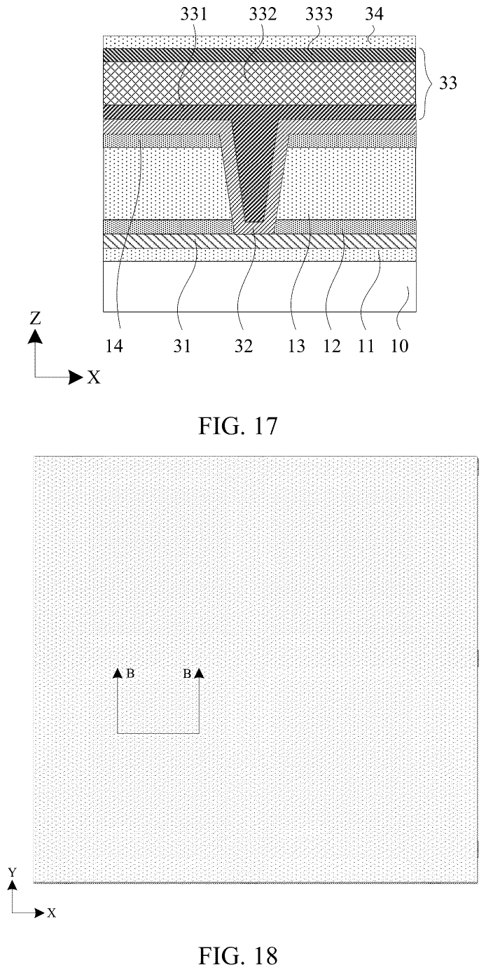

(7) A pattern of a second electrode is formed. In an exemplary implementation, forming the pattern of the second electrode may include depositing a second electrode conductive thin film on the base substrate on which the aforementioned patterns are formed, patterning the second electrode conductive thin film by a patterning process, to form the pattern of the second electrode 34 on the photoelectric conversion layer 33. The second electrode 34 is connected with the photoelectric conversion layer 33, as shown in FIG. 16 and FIG. 17, and FIG. 17 is a cross-sectional view taken along B-B direction in FIG. 16.

In an exemplary implementation, the second electrode 34 is directly connected with the photoelectric conversion layer 33 and a bias voltage provided by the second electrode 34 is transmitted to the photoelectric conversion layer 33.

In an exemplary embodiment, the second electrode conductive thin film may be made of a metal material, such as any one or more of Argentum (Ag), Copper (Cu), Aluminum (Al), Titanium (Ti), and Molybdenum (Mo), or an alloy material of the above metals, such as an Aluminum Neodymium alloy (AlNd) or a Molybdenum Niobium alloy (MoNb), and may be in a single-layer structure or a multi-layer composite structure, such as Ti/Al/Ti. Optionally, indium tin oxide (ITO) or indium zinc oxide (IZO) may be used as the second electrode conductive thin film.

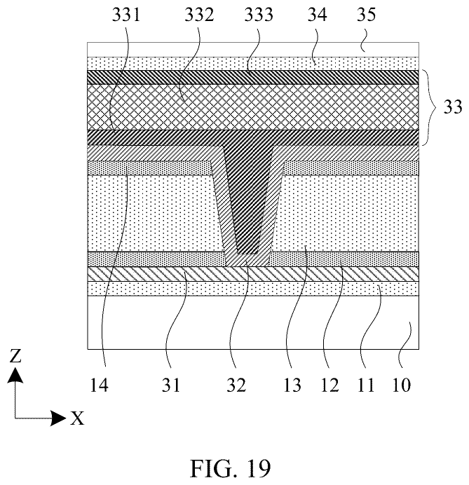

8) A protective layer is formed. In an exemplary implementation, forming the protective layer may include, depositing a protective layer thin film on the base substrate on which the aforementioned patterns are formed, patterning the protective layer thin film by a patterning process, to form a protective layer 35 on the second electrode 34, as shown in FIG. 18 and FIG. 19. FIG. 19 is a cross-sectional view taken along B-B direction in FIG. 18.

In an exemplary implementation, the protective layer 35 may be made of Polyethylene terephthalate (PET) .

So far, the sensing substrate and the detection layer are formed on the base substrate, the photoelectric conversion layer and the second electrode layer of the detection layer, and the first electrode layer in the sensing substrate may from a photodiode (Photo-Diode) in a photosensitive device. The PIN-type photodiode includes a first switch electrode 31, a photoelectric conversion layer 33, and a second electrode 34 and the photodiode is used for photoelectric conversion of incident light. In an exemplary implementation, a sensor includes a thin film transistor as a switch device and a PIN-type photodiode as a photosensitive device and the thin film transistor controls readout of an electrical signal in the photodiode.

In a sensing substrate and a sensing device provided by an embodiment of the present disclosure, an anti-static element is provided on a side of a fan-out region away from a sensing region, and at least part of signal wires in the sensing region are electrically connected with the anti-static element through fan-out wires in the fan-out region, which may be applied to a high PPI pixel specification.

The drawings of the embodiments of the present disclosure only involve structures involved in the embodiments of the present disclosure, and other structures may refer to a general design.

The embodiments of the present disclosure, that is, features in the embodiments, may be combined with each other to obtain a new embodiment if there is no conflict.

Although the implementations disclosed in the embodiments of the present disclosure are described above, contents are only implementations for facilitating understanding of the embodiments of the present disclosure, but are not intended to limit the embodiments of the present disclosure. Any person skilled in the art to which the embodiments of the present disclosure pertain may make any modifications and variations in forms and details of implementation without departing from the spirit and the scope disclosed in the embodiments of the present disclosure. Nevertheless, the scope of patent protection of the embodiments of the present disclosure shall still be subject to the scope defined by the appended claims.

1. A sensing substrate, comprising a sensing region, wherein the sensing region comprises a plurality of signal wires, on a plane parallel to the sensing substrate, an anti-static element and a fan-out region are provided on at least one side of the sensing region, the anti-static element is on a side of the fan-out region away from the sensing region, and at least part of the signal wires in the sensing region are electrically connected with the anti-static element through fan-out wires in the fan-out region.

2. The sensing substrate according to claim 1, further comprising a drive port, wherein the anti-static element comprises a first anti-static unit and the fan-out region comprises a first anti-static fan-out region;
on a plane parallel to the sensing substrate, the sensing region comprises a first side and a second side disposed opposite to each other along a first direction, on the first direction, the drive port is on a side of the first side away from the second side, the first anti-static unit is on a side of the second side away from the first side, and the first anti-static fan-out region is between the sensing region and the first anti-static unit.

3. The sensing substrate according to claim 2, wherein a size of a side of the first anti-static fan-out region close to the sensing region along a second direction is less than a size of a side of the first anti-static fan-out region close to the first anti-static unit along the second direction, on a plane parallel to the sensing substrate, the first direction intersects with the second direction.

4. The sensing substrate according to claim 2, wherein a bias element is further provided on at least one side of the sensing region, the first anti-static fan-out region comprises a third drive fan-out region and a fourth drive fan-out region, and the bias element comprises a first bias unit;
on the side of the second side away from the first side and along a direction from the first side to the second side, the third drive fan-out region, the first bias unit, the fourth drive fan-out region, and the first anti-static unit are sequentially arranged, one end of at least one fan-out wire in the third drive fan-out region is connected with at least part of the signal wires in the sensing region, and the other end of the at least one fan-out wire in the third drive fan-out region is electrically connected with the first anti-static unit through a fan-out wire in the fourth drive fan-out region.

5. The sensing substrate according to claim 4, wherein a size of a side of the third drive fan-out region close to the sensing region along a second direction is less than a size of a side of the third drive fan-out region close to the fourth drive fan-out region along the second direction; a size of a side of the fourth drive fan-out region close to the third drive fan-out region along the second direction is less than a size of a side of the fourth drive fan-out region close to the first anti-static unit along the second direction; or
on a plane parallel to the sensing substrate, a distance between the bias element and the sensing region is greater than or equal to 8.6 mm.

6. The sensing substrate according to claim 4, wherein the plurality of signal wires in the sensing region comprise a plurality of scan signal lines extending along the first direction and arranged at intervals along a second direction; the first anti-static unit comprises a plurality of first static discharge circuits arranged at intervals along the second direction; the first bias unit comprises a first bias structure layer; in a direction perpendicular to a plane where the sensing substrate is located, the sensing substrate comprises a base substrate, a first conductive layer disposed on the base substrate, a second conductive layer disposed on a side of the first conductive layer away from the base substrate, and a first electrode layer disposed on a side of the second conductive layer away from the base substrate;
the first conductive layer comprises a plurality of scan signal lines located in the sensing region and a plurality of third scan fan-out lines located in the third drive fan-out region and the plurality of third scan fan-out lines are configured to be connected with the plurality of scan signal lines of the sensing region;
the second conductive layer comprises a plurality of fourth scan fan-out lines located in the fourth drive fan-out region and the plurality of fourth scan fan-out lines are configured to respectively connect the plurality of third scan fan-out lines with the plurality of first static discharge circuits in a jumper manner; and
the first electrode layer comprises a first bias structure layer.

7. The sensing substrate according to claim 6, wherein the first bias unit further comprises a first bias auxiliary structure layer located at the first conductive layer, the first bias auxiliary structure layer is electrically connected with the first bias structure layer; an orthographic projection of the first bias structure layer on the base substrate is overlapped with an orthographic projection of the first bias auxiliary structure layer on the base substrate.

8. The sensing substrate according to claim 7, wherein the first bias unit further comprises a plurality of first bias bridge structures located at the second conductive layer, the plurality of first bias bridge structures extend along the first direction, are arranged at intervals along the second direction, and are electrically connected with the first bias structure layer and the first bias auxiliary structure layer;
the first bias structure layer and the first bias auxiliary structure layer are provided with a plurality of first hollow regions, so that the first bias unit forms a grid-like structure, an orthographic projection of the plurality of fourth scan fan-out lines on the base substrate is not overlapped with an orthographic projection of the plurality of first bias bridge structures on the base substrate, and the plurality of fourth scan fan-out lines respectively extend to the third drive fan-out region along the first direction through the intervals between the plurality of first bias bridge structures.

9. The sensing substrate according to claim 6, wherein the fan-out region further comprises a first drive fan-out region and a second drive fan-out region, the anti-static element further comprises a second anti-static unit, the second drive fan-out region is on a side of the first side away from the second side, the second anti-static unit is on a side of the second drive fan-out region away from the sensing region, the first drive fan-out region is on a side of the second anti-static unit away from the second drive fan-out region, the drive port is on a side of the first drive fan-out region away from the sensing region, the second anti-static unit is electrically connected with a fan-out wire in the first drive fan-out region and a fan-out wire in the second drive fan-out region, one end of at least one fan-out wire in the first drive fan-out region is electrically connected with a plurality of scan signal lines in the sensing region through a fan-out wire in the second drive fan-out region, and the other end of the at least one fan-out wire in the first drive fan-out region is electrically connected with the drive port.

10. The sensing substrate according to claim 9, wherein a size of a side of the second drive fan-out region close to the first drive fan-out region along the second direction is greater than a size of a side of the second drive fan-out region close to the sensing region along the second direction; a size of a side of the first drive fan-out region away from the second drive fan-out region along the second direction is less than a size of a side of the first drive fan-out region close to the second drive fan-out region along the second direction; or
wherein the sensing substrate further comprises a first power supply connection line and a second power supply connection line located at the second conductive layer and a third power supply connection line located at the first conductive layer; the second anti-static unit comprises a plurality of second static discharge circuits arranged at intervals along the second direction; on a plane parallel to the sensing substrate, the first power supply connection line and the second power supply connection line extend along the second direction, the third power supply connection line extends along the first direction, and the sensing region further comprises a third side and a fourth side disposed opposite to each other along the second direction;
the first power supply connection line is on a side of the second anti-static unit away from the sensing region and is electrically connected with a plurality of second static discharge circuits in the second anti-static unit;
the second power supply connection line is on the side of the second anti-static unit away from the sensing region and is electrically connected with a plurality of first static discharge circuits in the second anti-static unit; and
the third power supply connection line is on a side of the third side away from the fourth side and two ends of the third power supply connection line are electrically connected with the first power supply connection line and the second power supply connection line respectively.

11. (canceled)

12. The sensing substrate according to claim 10, further comprising: a fourth power supply connection line and a fifth power supply connection line located at the first conductive layer, on the second direction, the fourth power supply connection line and the fifth power supply connection line are at two sides of the first drive fan-out region and the first power supply connection line respectively, on the first direction, one end of the fourth power supply connection line is electrically connected with the first power supply connection line and the other end of the fourth power supply connection line is connected with the drive port, and one end of the fifth power supply connection line is electrically connected with the third power supply connection line and the other end of the fifth power supply connection line is connected with the drive port; or
wherein the bias element further comprises a third bias unit located on the side of the third side away from the fourth side, on the second direction, the third bias unit is between the sensing region and the third power supply connection line, and the third bias unit comprises a third bias structure layer located at the first electrode layer, a third bias auxiliary structure layer located at the first conductive layer, and a plurality of third bias bridge structures located at the second conductive layer;
the third bias auxiliary structure layer is electrically connected with the third bias structure layer and the third bias structure layer is electrically connected with the first bias structure layer; an orthographic projection of the third bias structure layer on the base substrate is overlapped with an orthographic projection of the third bias auxiliary structure layer on the base substrate;
the plurality of third bias bridge structures extend along the second direction, are arranged at intervals along the first direction, and are electrically connected with the third bias structure layer and the third bias auxiliary structure layer; and
the third bias structure layer and the third bias auxiliary structure layer are provided with a plurality of third hollow regions, so that the third bias unit forms a grid-like structure.

13. The sensing substrate according to claim 6, further comprising a read port, wherein the sensing region further comprises a third side and a fourth side disposed opposite to each other along the second direction, the fan-out region further comprises a first data fan-out region and a second data fan-out region, and the bias element further comprises a second bias unit; on the second direction, the second data fan-out region is on a side of the fourth side away from the third side, the first data fan-out region is on a side of the second data fan-out region away from the sensing region, the second bias unit is between the first data fan-out region and the second data fan-out region, the read port is on a side of the first data fan-out region away from the sensing region, one end of at least one fan-out wire in the first data fan-out region is electrically connected with at least part of the signal wires in the sensing region through a fan-out wire in the second data fan-out region, and the other end of the at least one fan-out wire in the first data fan-out region is electrically connected with the read port.

14. The sensing substrate according to claim 13, wherein the plurality of signal wires in the sensing region comprise a plurality of data signal lines located at the second conductive layer, the plurality of data signal lines extend along the second direction and are arranged at intervals along the first direction; the second bias unit comprises a second bias structure layer;
the second conductive layer further comprises a plurality of first data fan-out lines located in the first data fan-out region and a plurality of second data fan-out lines located in the second data fan-out region, the plurality of second data fan-out lines are configured to be connected with the plurality of data signal lines, and the plurality of first data fan-out lines are configured to connect the plurality of second data fan-out lines with the read port; and
the first electrode layer further comprises the second bias structure layer and the second bias structure layer is electrically connected with the first bias structure layer.

15. The sensing substrate according to claim 14, wherein the second bias unit further comprises a second bias auxiliary structure layer located at the first conductive layer and a plurality of second bias bridge structures located at the second conductive layer;
the second bias auxiliary structure layer is electrically connected with the second bias structure layer and an orthographic projection of the second bias structure layer on the base substrate is overlapped with an orthographic projection of the second bias auxiliary structure layer on the base substrate;
the plurality of second bias bridge structures extend along the second direction, are arranged at intervals along the first direction, and are electrically connected with the second bias structure layer and the second bias auxiliary structure layer;
the second bias structure layer and the second bias auxiliary structure layer are provided with a plurality of second hollow regions, so that the second bias unit forms a grid-like structure, an orthographic projection of the plurality of first data fan-out lines on the base substrate is not overlapped with an orthographic projection of the plurality of second bias bridge structures on the base substrate, and the plurality of first data fan-out lines respectively extend to the second drive fan-out region along the second direction through the intervals between the plurality of second bias bridge structures.

16. The sensing substrate according to claim 15, further comprising a first bias wire and a second bias wire located at the second conductive layer, wherein on the first direction, the first bias wire and the second bias wire are on two sides of the second bias unit and the first data fan-out region, on the second direction, the first bias wire and the second bias wire are on a side of the second bias unit away from the sensing region, each of the first bias wire and the second bias has one end connected with the second bias unit and the other end connected with the read port.

17. (canceled)

18. The sensing substrate according to claim 6, wherein the plurality of signal wires in the sensing region comprise a plurality of data signal lines located at the second conductive layer, the plurality of data signal lines extend along the second direction and are arranged at intervals along the first direction; the plurality of data signal lines and the plurality of scan signal lines define a plurality of pixel areas; at least part of the pixel area is provided with a thin film transistor and a first electrode, the first electrode is at the first electrode layer, and an orthographic projection of the first electrode on the base substrate is overlapped with an orthographic projection of a corresponding thin film transistor on the base substrate.

19. The sensing substrate according to claim 18, further comprising an insulation layer located between the second conductive layer and the first electrode layer on the direction perpendicular to the plane where the sensing substrate is located, wherein the insulation layer is provided with a plurality of first vias; the second conductive layer is further provided with a plurality of first switch electrodes, the plurality of first switch electrodes are integrally formed with source electrodes of corresponding thin film transistors, and the plurality of first electrodes are electrically connected with corresponding first switch electrodes through the plurality of first vias; an orthographic projection of the plurality of first vias on the base substrate is respectively overlapped with an orthographic projection of the plurality of first electrodes on the base substrate and an orthographic projection of the plurality of first switch electrodes on the base substrate.

20. The sensing substrate according to claim 19, wherein the first conductive layer further comprises gate electrodes of the thin film transistors, the gate electrodes are integrally formed with corresponding scan signal lines, a shape of each first switch electrode is polygonal, and on the second direction, the first switch electrode is on a side of a corresponding source electrode; a size of a side of the first switch electrode close to a corresponding source electrode along the first direction is less than a size of a side of the first switch electrode away from the corresponding source electrode along the first direction; an orthographic projection of a side of the first switch electrode connected with the corresponding source electrode on the base substrate is at least partially overlapped with an orthographic projection of a corresponding gate electrode on the base substrate, and one end of the first switch electrode away from the corresponding source electrode is electrically connected with a corresponding first electrode through a first via; or
wherein on the direction perpendicular to the plane where the sensing substrate is located, at least part of the first electrodes comprise a first functional layer and a second functional layer, the second functional layer is on a side of the first functional layer away from the base substrate, and an orthographic projection of the first functional layer on the base substrate is overlapped with and an orthographic projection of a corresponding second functional layer on the base substrate.

21-22. (canceled)

23. A sensing device, comprising a detection layer and the sensing substrate according to claim 1, wherein the sensing substrate comprises a base substrate and a read layer disposed on the base substrate and the detection layer is disposed on a side of the read layer away from the base substrate.

24. The sensing device according to claim 23, wherein on a plane parallel to the sensing substrate, the sensing substrate comprises a sensing region and the sensing region is provided with a plurality of first electrodes electrically connected with the read layer; in a direction perpendicular to a plane where the sensing substrate is located, the plurality of first electrodes are on a side of the read layer away from the base substrate, and the detection layer comprises a photoelectric conversion layer disposed on a side of the first electrodes away from the base substrate and a second electrode layer disposed on a side of the photoelectric conversion layer away from the base substrate;
on a plane parallel to the sensing substrate, a bias element is provided on at least one side of the sensing region and the bias element is electrically connected with the second electrode layer and configured to provide a bias voltage to the second electrode layer.
